(19) United States
(12) Patent Application Publication
(10) Pub. No.: US 2016/0268450 A1
(43) Pub. Date: Sep. 15, 2016

(54) PHOTOELECTRIC CONVERSION ELEMENT

(71) Applicant: SHARP KABUSHIKI KAISHA, Osaka-shi, Osaka (JP)

(72) Inventors: Kenji KIMOTO, Osaka-shi, Osaka (JP); Naoki KOIDE, Osaka-shi, Osaka (JP)

(21) Appl. No.: 15/031,904

(22) PCT Filed: Aug. 29, 2014
(86) PCT No.: PCT/JP2014/072686

§ 371 Date: Apr. 25, 2016

(30) Foreign Application Priority Data
Oct. 25, 2013 (JP) 2013-222803

(51) Int. Cl. H01L 31/0216; H01L 31/0288; H01L 31/0376

(52) U.S. Cl. CPC H01L 31/02167; H01L 31/0376; H01L 31/0288

(57) ABSTRACT

A photoelectric conversion element 100 includes an n-type monocrystalline silicon substrate 1, an non-crystalline thin film 2, i-type non-crystalline thin films 11 to 1m and 21 to 2m-1, p-type non-crystalline thin films 31 to 3m, and n-type non-crystalline thin films 41 to 4m-1. The non-crystalline thin film 2 is configured of non-crystalline thin films 201 and 202 and is disposed in contact with the surface on the light incident side of the n-type monocrystalline silicon substrate 1. The non-crystalline thin film 201 is configured of a-Si, and the non-crystalline thin film 202 is configured of a-SiNₓ (0<x<0.85) and is disposed further on the light incident side than the non-crystalline thin film 201. The i-type non-crystalline thin films 11 to 1m and 21 to 2m-1 are disposed in contact with the rear surface of the n-type monocrystalline silicon substrate 1. The p-type non-crystalline thin films 31 to 3m are disposed in contact with the i-type non-crystalline thin films 11 to 1m. The n-type non-crystalline thin films 41 to 4m-1 are disposed in contact with the i-type non-crystalline thin films 21 to 2m-1.

### TECHNICAL FIELD

The present invention relates to a photoelectric conversion element.

### BACKGROUND ART

The important things in order to achieve high conversion efficiency in a solar cell are suppressing reflection of light on the light-receiving surface side of the solar cell and suppressing carrier recombination on the light-receiving surface side of the solar cell. Thus, a passivation film and an antireflection coat are disposed on the light-receiving surface side of the solar cell. The antireflection coat may double as the passivation film.

In PTL 1, for example, there is disclosed a heterojunction type solar cell. In the solar cell of PTL 1, intrinsic non-crystalline silicon, p-type non-crystalline silicon, and a transparent conductive film are formed on the light-receiving surface side of an n-type monocrystalline silicon substrate. In the solar cell of such a configuration, a strong interface state passivation effect is achieved in the interface between the non-crystalline silicon and the n-type monocrystalline silicon substrate. Thus, carrier recombination can be suppressed on the light-receiving surface side. The transparent conductive film can be used as the antireflection coat.

In PTL 2, there is disclosed a back contact type solar cell.

The back contact type solar cell is a solar cell in which p-n junctions and electrodes that are formed on the light-receiving surface side in the related art are formed on the rear surface side of the solar cell to prevent shadows due to electrodes on the light-receiving surface side and further absorb sunlight, thereby achieving high efficiency.

For this type of solar cell, there is suggested a solar cell that uses heterojunctions as the p-n junctions (PTL 1). This solar cell has a structure configured by stacking type amorphous silicon (a-Si) and n-type a-Si in order on the rear surface of a semiconductor substrate, removing a part of each of the stacked i-type a-Si and the n-type a-Si, and stacking i-type a-Si and p-type a-Si in order in the removed part.

An antireflection layer that is configured of a silicon nitride layer is formed on the light-receiving surface side of the solar cell of PTL 2.

PTL 1: Japanese Unexamined Patent Application Publication No. 4-130671

PTL 2: Japanese Unexamined Patent Application Publication No. 2010-80887

### DISCLOSURE OF INVENTION

However, in a case of forming a silicon nitride layer directly on the surface on the light incident side of a monocrystalline silicon substrate as in the solar cell of PTL 2, high passivation characteristics are unlikely to be achieved as compared with a case of forming an non-crystalline silicon film as in the solar cell of PTL 1.

In a case of passivating the surface on the light incident side of a monocrystalline silicon substrate with an non-crystalline silicon film as in the solar cell of PTL 1, bonds between silicon (Si) and hydrogen (H) in the non-crystalline silicon film are cleaved by ultraviolet light, and passivation characteristics are decreased, thereby posing the problem of photodegradation of the solar cell.

Therefore, according to an embodiment of the invention, there is provided a photoelectric conversion element that can suppress photodegradation.

In addition, according to an embodiment of the invention, there is provided a photoelectric conversion module that includes a photoelectric conversion element capable of suppressing photodegradation.

Furthermore, according to an embodiment of the invention, there is provided a solar power generation system that includes a photoelectric conversion element capable of suppressing photodegradation.

According to an embodiment of the invention, the photoelectric conversion element includes a semiconductor substrate, a passivation film, and an non-crystalline thin film. The passivation film is disposed on a surface on a light incident side of the semiconductor substrate and includes a hydrogen atom. The non-crystalline thin film is disposed further on the light incident side than the passivation film. The non-crystalline thin film absorbs at least a part of light having a wavelength corresponding to energy greater than or equal to bond energy between the hydrogen atom and an atom other than the hydrogen atom constituting the passivation film.

In the photoelectric conversion element according to the embodiment of the invention, the non-crystalline thin film absorbs at least a part of light having a wavelength corresponding to energy greater than or equal to bond energy between the hydrogen atom and an atom other than the hydrogen atom constituting the passivation film. As a result, a bond between the hydrogen atom and an atom other than the hydrogen atom constituting the passivation film is unlikely to be cleaved in the passivation film, and an increase of defects is suppressed. In addition, a decrease of an open-circuit voltage is suppressed when the photoelectric conversion element is irradiated with ultraviolet light.

Therefore, photodegradation of the photoelectric conversion element can be suppressed.

It is preferable that the optical band gap of the non-crystalline thin film is greater than the optical band gap of the passivation film.

An optical short-circuit current can be increased by reducing absorption of light by the non-crystalline thin film.

It is preferable that the non-crystalline thin film includes a main constituent element of the passivation film and a desired element that is for setting the optical band gap of the non-crystalline thin film to an optical band gap greater than the optical band gap of the passivation film.

The non-crystalline thin film includes a main constituent element of the passivation film and a desired element. Thus, the non-crystalline thin film can be formed contiguously on the passivation film by adding a material gas of the desired element. As a result, defects can be decreased in the interface between the non-crystalline thin film and the passivation film.

It is preferable that the passivation film includes an Si—H bond and that the wavelength is less than or equal to 365 nm.

The Si—H bond in the passivation film is unlikely to be cleaved, and passivation characteristics for the semiconductor substrate can be improved.

It is preferable that the non-crystalline thin film is configured of a silicon nitride film.

The non-crystalline thin film can function as an antireflection coat.

It is preferable that the composition ratio of nitrogen atoms with respect to silicon atoms in the non-crystalline thin film is greater than 0 and less than 0.85.

The light absorption coefficient of the non-crystalline thin film is increased, and the non-crystalline thin film absorbs more ultraviolet light. As a result, an increase of defects in the passivation film is effectively suppressed, and a decrease of an open-circuit voltage is effectively suppressed when the photoelectric conversion element is irradiated with ultraviolet light.

Therefore, by controlling the composition ratio of nitrogen atoms, photodegradation of the photoelectric conversion element can be effectively suppressed.

It is preferable that the composition ratio of nitrogen atoms with respect to silicon atoms in the non-crystalline thin film is greater than 0 and less than or equal to 0.78.

By setting the thickness of the non-crystalline thin film to a desired value, the non-crystalline thin film can function as an antireflection coat and as an absorption layer that absorbs light having a wavelength corresponding to large energy greater than or equal to the bond energy between the hydrogen atom and an atom other than the hydrogen atom constituting the passivation film.

It is preferable that the passivation film includes hydrogenated non-crystalline silicon.

Passivation characteristics for the semiconductor substrate can be further improved.

It is preferable that the non-crystalline thin film is arranged in contact with the passivation film and that the composition ratio of the desired element is increased from the semiconductor substrate side of the photoelectric conversion element toward the light incident side thereof.

The refractive indexes of the non-crystalline thin film and the passivation film are distributed in such a manner to be decreased from the light incident side toward the semiconductor substrate side.

Therefore, an increase of defects in the passivation film can be suppressed by absorbing ultraviolet light, and the reflectance can be further decreased on the surface on the light incident side of the photoelectric conversion element.

It is preferable that the composition ratio of the desired element is stepwise increased from the semiconductor substrate side of the photoelectric conversion element toward the light incident side.

A refractive index distribution for decreasing the reflectance in the non-crystalline thin film can be easily realized.

It is preferable that the photoelectric conversion element further includes first and second conductivity type thin films. The first conductivity type thin film is disposed on the rear surface of the semiconductor substrate on the opposite side to the surface on the light incident side thereof and has an opposite conductivity type to the conductivity type of the semiconductor substrate. The second conductivity type thin film is disposed on the rear surface of the semiconductor substrate on the opposite side to the surface on the light incident side thereof and is disposed in a part or the entirety of a region in which the first conductivity type thin film is not disposed and has the same conductivity side as the conductivity type of the semiconductor substrate.

The rear surface of the semiconductor substrate is also passivated, and characteristics of the photoelectric conversion element can be further improved.

It is preferable that the photoelectric conversion element further includes a third conductivity type thin film. The third conductivity type thin film is arranged between the first and second conductivity type thin films and the semiconductor substrate and substantially has a conductivity type of i-type.

Passivation characteristics of the rear surface of the semiconductor substrate can be further improved.

It is preferable that the semiconductor substrate is an n-type monocrystalline silicon substrate, the first conductivity type thin film is p-type non-crystalline silicon, and the second conductivity type thin film is n-type non-crystalline silicon.

The photoelectric conversion element can be manufactured by a low-temperature process such as plasma CVD, and a decrease of carrier characteristics can be suppressed by reducing thermal strains in the n-type monocrystalline silicon substrate.

According to an embodiment of the invention, the photoelectric conversion module includes the photoelectric conversion element according to any one of Claims 1 to 13.

The reliability of the photoelectric conversion module can be increased.

According to an embodiment of the invention, the solar power generation system includes the photoelectric conversion module according to Claim 14.

The reliability of the solar power generation system can be increased.

In the photoelectric conversion element according to the embodiment of the invention, the non-crystalline thin film absorbs at least a part of light having a wavelength corresponding to energy greater than or equal to bond energy between the hydrogen atom and an atom other than the hydrogen atom constituting the passivation film. As a result, a bond between the hydrogen atom and an atom other than the hydrogen atom constituting the passivation film is unlikely to be cleaved in the passivation film, and an increase of defects is suppressed. In addition, a decrease of an open-circuit voltage is suppressed when the photoelectric conversion element is irradiated with ultraviolet light.

Therefore, photodegradation of the photoelectric conversion element can be suppressed.

According to an embodiment of the invention, the photoelectric conversion module and the solar power generation system include the photoelectric conversion element that is subject to less photodegradation.

Therefore, the reliability of the photoelectric conversion module and the solar power system can be increased.

### BRIEF DESCRIPTION OF DRAWINGS

FIG. 1 is a sectional view illustrating a configuration of a photoelectric conversion element according to a first embodiment of the invention.

FIG. 2 is a first process chart illustrating a manufacturing method for the photoelectric conversion element illustrated in FIG. 1.

FIG. 3 is a second process chart illustrating a manufacturing method for the photoelectric conversion element illustrated in FIG. 1.

FIG. 4 is a third process chart illustrating a manufacturing method for the photoelectric conversion element illustrated in FIG. 1.

FIG. 5 is a diagram illustrating a relationship between the absorption coefficient of a-SiNₓ and a composition ratio of nitrogen atoms.

FIG. 6 is a diagram illustrating a relationship between the transmittance of a-SiNₓ and the composition ratio of nitrogen atoms.

FIG. 7 is a diagram illustrating a relationship between the film thickness of a-SiNₓ in which the transmittance of light having a wavelength of 365 nm is 90% and the composition ratio of nitrogen atoms.

FIG. 8 is a diagram illustrating a relationship between the film thickness of a-SiNₓ in which the transmittance is 90% and the composition ratio of nitrogen atoms.

FIG. 9 is a diagram illustrating a result of a light irradiation test for the photoelectric conversion element.

FIG. 10 is a diagram illustrating a distribution of the composition ratio of nitrogen atoms in a thickness direction.

FIG. 11 is a sectional view illustrating a configuration of a photoelectric conversion element according to a second embodiment.

FIG. 12 is a partial process chart for manufacturing the photoelectric conversion element illustrated in FIG. 11.

FIG. 13 is a partial process chart for manufacturing the photoelectric conversion element illustrated in FIG. 11.

FIG. 14 is a sectional view illustrating a configuration of a photoelectric conversion element according to a third embodiment.

FIG. 15 is a partial process chart for manufacturing the photoelectric conversion element illustrated in FIG. 14.

FIG. 16 is a partial process chart for manufacturing the photoelectric conversion element illustrated in FIG. 14.

FIG. 17 is a sectional view illustrating a configuration of a photoelectric conversion element according to a fourth embodiment.

FIG. 18 is a partial process chart for manufacturing the photoelectric conversion element illustrated in FIG. 17.

FIG. 19 is a partial process chart for manufacturing the photoelectric conversion element illustrated in FIG. 17.

FIG. 20 is a sectional view illustrating a configuration of a photoelectric conversion element according to a fifth embodiment.

FIG. 21 is a first process chart illustrating a manufacturing method for the photoelectric conversion element illustrated in FIG. 20.

FIG. 22 is a second process chart illustrating a manufacturing method for the photoelectric conversion element illustrated in FIG. 20.

FIG. 23 is a third process chart illustrating a manufacturing method for the photoelectric conversion element illustrated in FIG. 20.

FIG. 24 is a fourth process chart illustrating a manufacturing method for the photoelectric conversion element illustrated in FIG. 20.

FIG. 25 is a sectional view illustrating a configuration of a photoelectric conversion element according to a sixth embodiment.

FIG. 26 is a sectional view illustrating a configuration of a photoelectric conversion element according to a seventh embodiment.

FIG. 27 is a first process chart illustrating a manufacturing method for the photoelectric conversion element illustrated in FIG. 26.

FIG. 28 is a second process chart illustrating a manufacturing method for the photoelectric conversion element illustrated in FIG. 26.

FIG. 29 is a third process chart illustrating a manufacturing method for the photoelectric conversion element illustrated in FIG. 26.

FIG. 30 is a fourth process chart illustrating a manufacturing method for the photoelectric conversion element illustrated in FIG. 26.

FIG. 31 is a sectional view illustrating a configuration of a photoelectric conversion element according to an eighth embodiment.

FIG. 32 is a sectional view illustrating a configuration of a photoelectric conversion element according to a ninth embodiment.

FIG. 33 is a schematic diagram illustrating a configuration of a photoelectric conversion module that includes the photoelectric conversion element according to the above embodiments.

FIG. 34 is a schematic diagram illustrating a configuration of a solar power generation system that includes the photoelectric conversion element according to the above embodiments.

FIG. 35 is a schematic diagram illustrating a configuration of a photoelectric conversion module array illustrated in FIG. 34.

FIG. 36 is a schematic diagram illustrating a configuration of a solar power generation system that includes the photoelectric conversion element according to the above embodiments.

### BEST MODES FOR CARRYING OUT THE INVENTION

Embodiments of the present invention will be described in detail with reference to the drawings. The same or corresponding parts in the drawings will be designated by the same reference sign, and descriptions thereof will not be repeated.

In this specification, the term “non-crystalline phase” refers to a state in which silicon (Si) atoms and the like are non-periodically arranged. The term “non-crystalline thin film” means a thin film that includes at least an non-crystalline phase and also includes a case where a thin film is completely configured of an non-crystalline phase and a case where a thin film is configured to include both a crystalline phase and an non-crystalline phase. The term “non-crystalline thin film” also includes a case where a thin film is completely configured of an non-crystalline phase (non-crystalline silicon) and a case where a thin film includes a crystalline phase, such as microcrystalline silicon or crystalline silicon grown from a crystalline silicon substrate, in non-crystalline silicon. While amorphous silicon is represented as “a-Si”, this representation actually means that hydrogen (H) atoms are included therein. Similarly, regarding amorphous silicon carbide (a-SiC), amorphous silicon oxide (a-SiO), amorphous silicon nitride (a-SiN), amorphous silicon oxynitride (a-SiON), amorphous silicon carbon nitride (a-SiCN), amorphous silicon germanium (a-SiGe), and amorphous germanium (a-Ge), these representations mean that H atoms are included therein and also include a case where a thin film is completely configured of an non-crystalline phase and a case where a thin film includes both an non-crystalline phase and a crystalline phase.

### First Embodiment

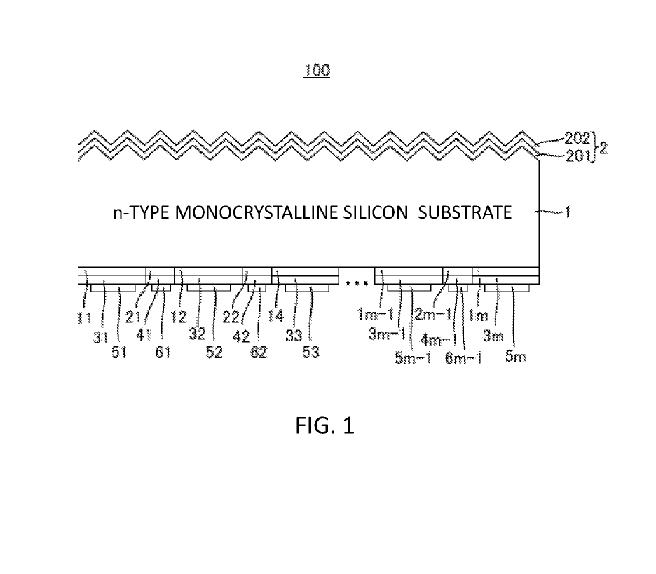

FIG. 1 is a sectional view illustrating a configuration of a photoelectric conversion element according to a first embodiment of the invention. With reference to FIG. 1, a photoelectric conversion element 100 according to the first embodiment of the invention includes an n-type monocrystalline silicon substrate 1, an non-crystalline thin film 2, i-type non-crystalline thin films 11 to 1m and 21 to 2m-1 (m is an integer greater than or equal to two), p-type non-crystalline thin films 31 to 3m, n-type non-crystalline thin films 41 to 4m-1, and electrodes 51 to 5m and 61 to 6m-1.

The n-type monocrystalline silicon substrate 1 has, for example, a (100) plane orientation and a resistivity of 0.1 Ω·cm to 10 Ω·cm. The n-type monocrystalline silicon substrate 1 has, for example, a thickness of 50 μm to 300 μm and preferably a thickness of 80 μm to 200 μm. The surface on the light incident side of the n-type monocrystalline silicon substrate 1 is texturized.

The non-crystalline thin film 2 is disposed on the n-type monocrystalline silicon substrate 1 in contact with the surface on the light incident side of the n-type monocrystalline silicon substrate 1. The non-crystalline thin film 2 is configured of non-crystalline thin films 201 and 202.

The non-crystalline thin film 201 includes at least an non-crystalline phase and is configured of, for example, a-Si. A crystalline phase such as microcrystalline silicon may be included in the non-crystalline thin film 201. The non-crystalline thin film 201 has a thickness of, for example, 1 nm to 20 nm. The non-crystalline thin film 201 is disposed on the n-type monocrystalline silicon substrate 1 in contact with the surface on the light incident side of the n-type monocrystalline silicon substrate 1 to passivate the n-type monocrystalline silicon substrate 1.

The non-crystalline thin film 202 includes at least an non-crystalline phase and is configured of, for example, a-SiNₓ (x is a real number satisfying 0<x<0.85). A crystalline phase such as microcrystalline silicon may be included in the non-crystalline thin film 202. The non-crystalline thin film 202 is arranged further on the light incident side than the non-crystalline thin film 201 and is in contact with the non-crystalline thin film 201. The non-crystalline thin film 202 has a thickness corresponding to each composition ratio x as described later. The non-crystalline thin film 202 absorbs, of light that is incident on the photoelectric conversion element 100, at least a part of light having energy greater than or equal to the bond energy of an Si—H bond (3.4 eV), that is, light having a wavelength less than or equal to 365 nm (hereinafter, called “ultraviolet light”).

Each of the i-type non-crystalline thin films 11 to 1m and 21 to 2m-1 includes at least an non-crystalline phase and is disposed in contact with the rear surface on the opposite side of the n-type monocrystalline silicon substrate 1 to the light incident side. Each of the i-type non-crystalline thin films 11 to 1m and 21 to 2m-1 is configured of, for example, i-type a-Si and has a thickness of, for example, 10 nm. A crystalline phase such as microcrystalline silicon may be included in each of the i-type non-crystalline thin films 11 to 1m and 21 to 2m-1.

The p-type non-crystalline thin films 31 to 3m are disposed in contact with the i-type non-crystalline thin films 11 to 1m. Each of the p-type non-crystalline thin films 31 to 3m includes at least an non-crystalline phase and is configured of, for example, p-type a-Si. A crystalline phase such as microcrystalline silicon may be included in each of the p-type non-crystalline thin films 31 to 3m. Each of the p-type non-crystalline thin films 31 to 3m has a thickness of, for example, 10 nm. The p-type non-crystalline thin films 31 to 3m are arranged at desired intervals in the in-plane direction of the n-type monocrystalline silicon substrate 1. The concentration of boron (B) in each of the p-type non-crystalline thin films 31 to 3m is, for example, 1×10²⁰ cm⁻³.

The n-type non-crystalline thin films 41 to 4m-1 are respectively disposed in contact with the i-type non-crystalline thin films 21 to 2m-1. Each of the n-type non-crystalline thin films 41 to 4m-1 includes at least an non-crystalline phase and is configured of, for example, n-type a-Si. Each of the n-type non-crystalline thin films 41 to 4m-1 has a thickness of, for example, 10 nm. A crystalline phase such as microcrystalline silicon may be included in each of the n-type non-crystalline thin films 41 to 4m-1. The concentration of phosphorus (P) in each of the n-type non-crystalline thin films 41 to 4m-1 is, for example, 1×10²⁰ cm⁻³.

The electrodes 51 to 5m are respectively disposed in contact with the p-type non-crystalline thin films 31 to 3m. The electrodes 61 to 6m-1 are respectively disposed in contact with the n-type non-crystalline thins films 41 to 4m-1. Each of the electrodes 51 to 5m and 61 to 6m-1 is configured of, for example, silver (Ag).

The p-type non-crystalline thin films 31 to 3m and the n-type non-crystalline thin films 41 to 4m-1 have the same length in a direction perpendicular to the page of FIG. 1. The area occupancy that is the proportion of the area of the n-type monocrystalline silicon substrate 1 occupied by the area of all of the p-type non-crystalline thin films 31 to 3m is, for example, 50% to 95%, and the area occupancy that is the proportion of the area of the n-type monocrystalline silicon substrate 1 occupied by the area of all of the n-type non-crystalline thin films 41 to 4m-1 is, for example, 5% to 50%.

As such, the reason why the area occupancy made by the p-type non-crystalline thin films 31 to 3m is rendered greater than the area occupancy made by the n-type non-crystalline thin films 41 to 4m-1 is that optically excited electrons and electron holes are likely to be separated by p-n junctions (p-type non-crystalline thin films 31 to 3m/n-type monocrystalline silicon substrate 1) in the n-type monocrystalline silicon substrate 1 and that the ratio of optically excited electrons and electron holes contributing to power generation is increased.

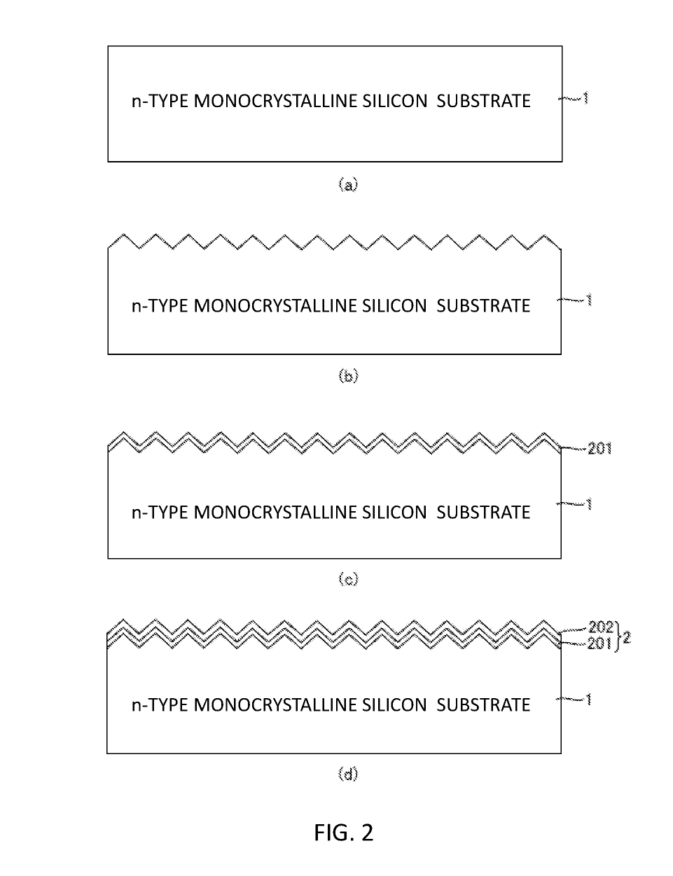

FIG. 2 to FIG. 4 are respectively first to third process charts illustrating a manufacturing method for the photoelectric conversion element 100 illustrated in FIG. 1.

A manufacturing method for the photoelectric conversion element 100 will be described. Generally, the non-crystalline thin film 2 used in the photoelectric conversion element 100 is deposited by plasma chemical vapour deposition (CVD) with use of a plasma CVD apparatus.

The plasma CVD apparatus includes, for example, an RF power supply that applies an RF power of 13.56 MHz to parallel plate electrodes through a matcher.

If manufacturing of the photoelectric conversion element 100 is started, the n-type monocrystalline silicon substrate 1 is degreased by ultrasonic cleaning using ethanol or the like (refer to Process (a) of FIG. 2). Anisotropic etching is chemically performed on the surface of the n-type monocrystalline silicon substrate 1 by using alkalis to texturize the surface of the n-type monocrystalline silicon substrate 1 (refer to Process (b) of FIG. 2).

Then, the n-type monocrystalline silicon substrate 1 is immersed in hydrofluoric acid to remove a natural oxide film formed on the surface of the n-type monocrystalline silicon substrate 1 and to terminate the surface of the n-type monocrystalline silicon substrate 1 with hydrogen.

If the cleaning of the n-type monocrystalline silicon substrate 1 is ended, the n-type monocrystalline silicon substrate 1 is put into a reaction chamber of the plasma CVD apparatus.

A silane (SiH₄) gas is caused to flow into the reaction chamber. The pressure of the reaction chamber is set to, for example, 30 Pa to 600 Pa, and the temperature of the substrate is set to, for example, 100° C. to 300° C. Then, the RF power supply applies the RF power to the parallel plate electrodes through the matcher. Accordingly, plasma is generated in the reaction chamber, and the non-crystalline thin film 201 configured of a-Si is accumulated on the surface on the light incident side (=surface on which a texture structure is formed) of the n-type monocrystalline silicon substrate 1 (refer to Process (c) of FIG. 2).

If the thickness of the non-crystalline thin film 201 reaches 10 nm, the RF power is stopped, and an SiH₄ gas and an ammonia (NH₃) gas are caused to flow into the reaction chamber in such a manner that the flow ratio NH₃/SiH₄ of the NH₃ gas to the SiH₄ gas is, for example, 0 to 20 and preferably 0 to 2. The pressure of the reaction chamber is set to, for example, 30 Pa to 600 Pa, and the RF power supply applies the RF power to the parallel plate electrodes through the matcher. Accordingly, the non-crystalline thin film 202 configured of a-SiNₓ (0<x<0.85) is accumulated on the non-crystalline thin film 201 (refer to Process (d) of FIG. 2). As a result, the non-crystalline thin film 2 is formed on the surface on the light incident side of the n-type monocrystalline silicon substrate 1.

Then, the non-crystalline thin film 2/n-type monocrystalline silicon substrate 1 is withdrawn from the plasma CVD apparatus, and the non-crystalline thin film 2/n-type monocrystalline silicon substrate 1 is put into the plasma CVD apparatus in such a manner that a thin film can be accumulated on the rear surface (surface on the opposite side to the surface on which the non-crystalline thin film 2 is formed) of the n-type monocrystalline silicon substrate 1.

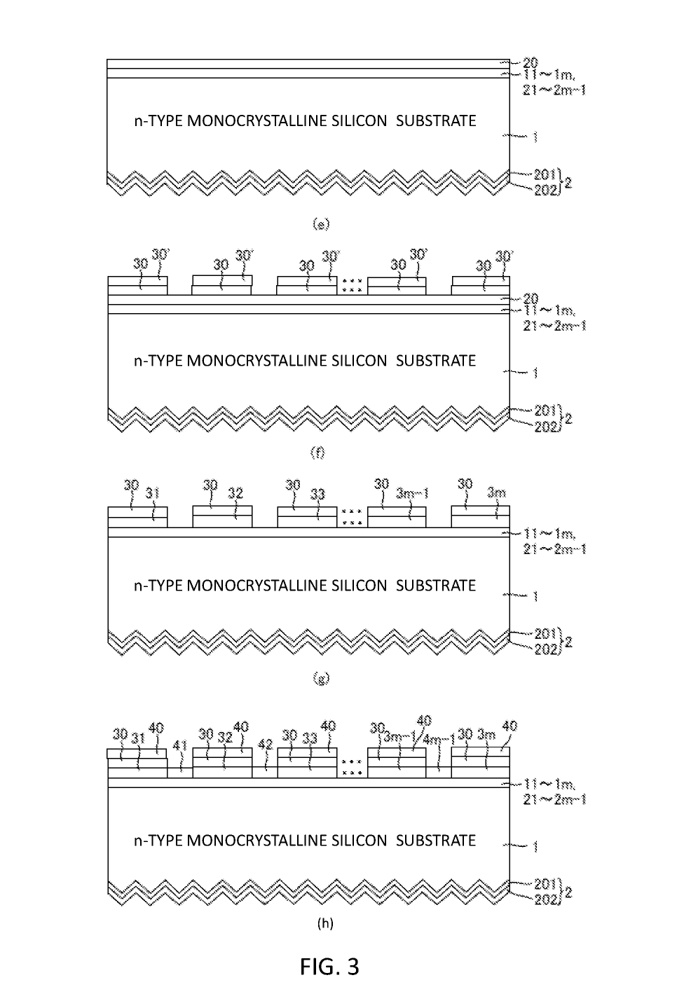

An SiH₄ gas is caused to flow into the reaction chamber. The pressure of the reaction chamber is set to, for example, 30 Pa to 600 Pa, and the temperature of the substrate is set to, for example, 100° C. to 300° C. The RF power supply applies the RF power to the parallel plate electrodes through the matcher. Accordingly, the i-type non-crystalline thin films 11 to 1m and 21 to 2m-1 configured of i-type a-Si are accumulated on the n-type monocrystalline silicon substrate 1. Then, an SiH₄ gas and a diborane (B₂H₆) gas are caused to flow into the reaction chamber. The pressure of the reaction chamber is set to, for example, 30 Pa to 600 Pa, and the RF power supply applies the RF power to the parallel plate electrodes through the matcher. Accordingly, a p-type non-crystalline thin film 20 that is configured of p-type a-Si is accumulated on the i-type non-crystalline thin films 11 to 1m and 21 to 2m-1 (refer to Process (e) of FIG. 3).

Then, an SiH₄ gas and an NH₃ gas are caused to flow into the reaction chamber. The pressure of the reaction chamber is set to, for example, 30 Pa to 600 Pa, and the RF power supply applies the RF power to the parallel plate electrodes through the matcher. Accordingly, a cladding layer that is configured of a-SiN is formed on the p-type non-crystalline thin film 20. The cladding layer may be configured of silicon oxide. A resist pattern is formed on the cladding layer by photolithography, and then, the cladding layer in opening portions of the resist is etched by using hydrofluoric acid or the like to form cladding layers 30 that are arranged at desired intervals on the p-type non-crystalline thin film 20 (refer to Process (f) of FIG. 3).

Next, the p-type non-crystalline thin film 20 is etched by dry etching or wet etching with resists 30′ and the cladding layers 30 as a mask to form the p-type non-crystalline thin films 31 to 3m (refer to Process (g) of FIG. 3). Then, the resists 30′ are removed.

If the p-type non-crystalline thin films 31 to 3m are formed, an SiH₄ gas and a phosphine (PH₃) gas are caused to flow into the reaction chamber. The pressure of the reaction chamber is set to, for example, 30 Pa to 600 Pa, and the RF power supply applies the RF power to the parallel plate electrodes through the matcher. Accordingly, the n-type non-crystalline thin films 41 to 4m-1 configured of n-type a-Si are respectively accumulated on the i-type non-crystalline thin films 21 to 2m-1 in contact with the i-type non-crystalline thin films 21 to 2m-1, and n-type non-crystalline thin films 40 that are configured of n-type a-Si are accumulated on the cladding layers 30 (refer to Process (h) of FIG. 3).

If the n-type non-crystalline thin films 41 to 4m-1 are accumulated on the i-type non-crystalline thin films 21 to 2m-1, the non-crystalline thin film 2/n-type monocrystalline silicon substrate 1/i-type non-crystalline thin films 11 to 1m and 21 to 2m-1/p-type non-crystalline thin films 31 to 3m and n-type non-crystalline thin films 41 to 4m-1/cladding layers 30/n-type non-crystalline thin films 40 are withdrawn from the plasma CVD apparatus.

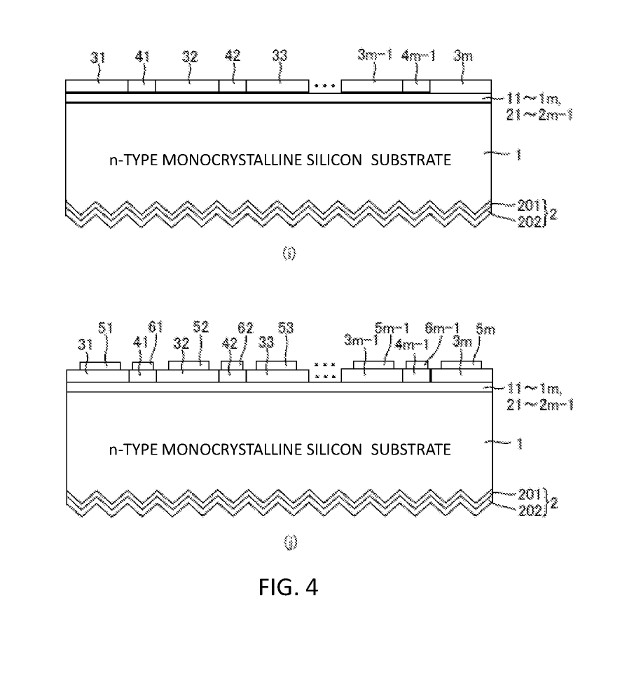

The cladding layers 30 are removed by etching using, for example, hydrofluoric acid. Accordingly, the n-type non-crystalline thin films 40 are removed by being lift-off (refer to Process (i) of FIG. 4).

Next, Ag is vapour-deposited on all of the surfaces of the n-type non-crystalline thin films 41 to 4m-1 and the p-type non-crystalline thin films 31 to 3m, and the vapour-deposited Ag is patterned by photolithography and etching to form the electrodes 51 to 5m and 61 to 6m-1. Accordingly, the photoelectric conversion element 100 is completed (refer to Process (j) of FIG. 4).

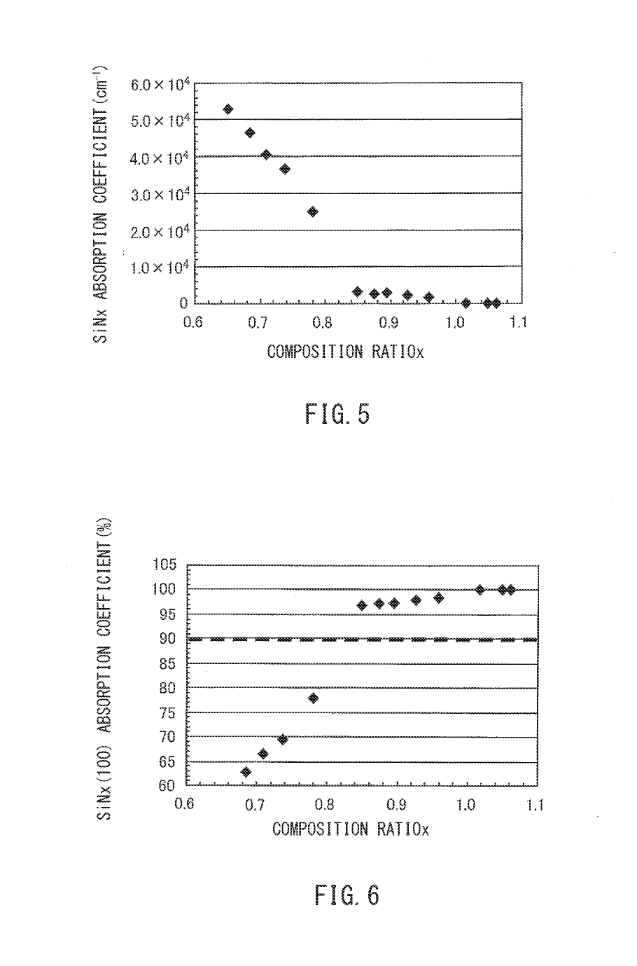

FIG. 5 is a diagram illustrating a relationship between the absorption coefficient of a-SiNₓ and a composition ratio of nitrogen atoms. In FIG. 5, the vertical axis represents the absorption coefficient of a-SiNₓ, and the horizontal axis represents the composition ratio x of nitrogen atoms. The composition ratio x is measured by Auger electron spectroscopy. The absorption coefficient illustrated in FIG. 5 is the absorption coefficient of a-SiNₓ in a wavelength λ of 365 nm obtained by experiment. The Si—H bond energy is 3.4 eV. If the non-crystalline thin film 201 is irradiated with light having a wavelength less than or equal to 365 nm, Si—H bonds are likely to be cleaved, thereby causing photodegradation. The reason why the a-SiNₓ absorption ratio in 365 nm is used is that the degree to which light having a wavelength less than or equal to 365 nm does not reach the a-Si constituting the non-crystalline thin film 201 can be found by the absorption coefficient of a-SiNₓ in 365 nm, with the result of measurement that the absorption coefficient is increased as the wavelength of light is decreased. That is, the reason is that the degree to which the Si—H bonds in the a-Si constituting the non-crystalline thin film 201 are not cleaved by light having a wavelength less than or equal to 365 nm can be found.

With reference to FIG. 5, the absorption coefficient of a-SiNₓ is less than or equal to 3.1×10³ (cm⁻¹) in the range of the composition ratio x of nitrogen atoms greater than or equal to 0.85 but is rapidly increased as the composition ratio x of nitrogen atoms becomes less than 0.85 and is 2.50×10⁴ (cm⁻¹) to 5.29×10⁴ (cm⁻¹) in the range of 0.651≦x≦0.78. Therefore, as the composition ratio x of nitrogen atoms becomes less than 0.85, the absorption coefficient of a-SiNₓ is significantly increased.

FIG. 6 is a diagram illustrating a relationship between the transmittance of a-SiNₓ and the composition ratio of nitrogen atoms. In FIG. 6, the vertical axis represents the transmittance of a-SiNₓ, and the horizontal axis represents the composition ratio x of nitrogen atoms. The transmittance illustrated in FIG. 6 is the transmittance of a-SiNₓ in the wavelength of 365 nm calculated by using the absorption coefficient in the wavelength of 365 nm, and the film thickness of a-SiNₓ is 100 nm.

With reference to FIG. 6, the transmittance of a-SiNₓ is 96.95(%) to 100(%) in the range of the composition ratio x of nitrogen atoms from 0.85 to 1.062 but is rapidly decreased as the composition ratio x of nitrogen atoms becomes less than 0.85 and is 58.9(%) to 77.92(%) in the range of the composition ratio x of nitrogen atoms from 0.651 to 0.78.

As such, the reason why the transmittance of a-SiNₓ is rapidly decreased as the composition ratio x becomes less than 0.85 is that the absorption coefficient of a-SiNₓ is rapidly increased as the composition ratio x becomes less than 0.85 as illustrated in FIG. 5.

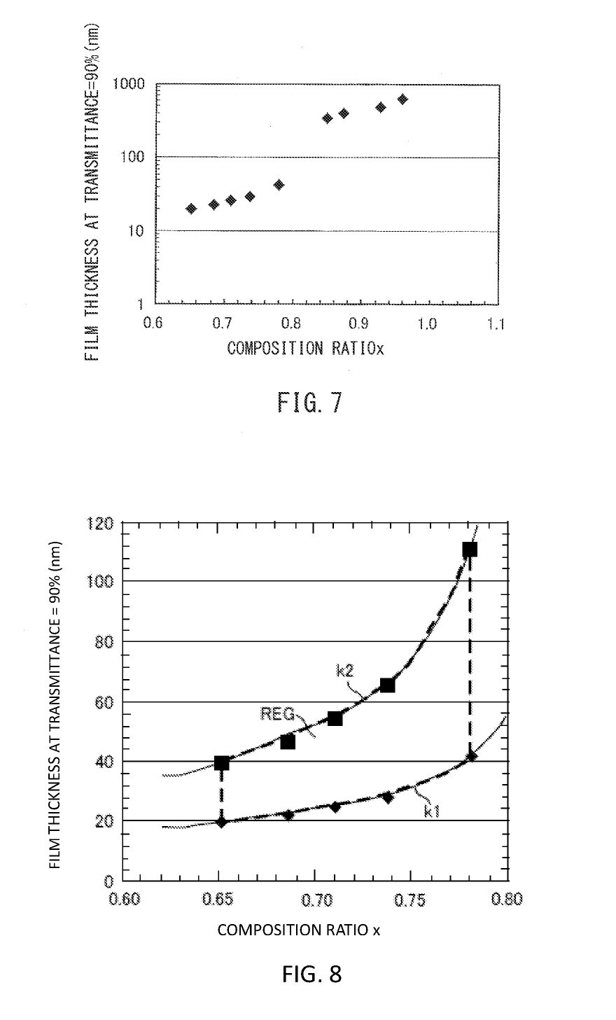

FIG. 7 is a diagram illustrating a relationship between the film thickness of a-SiNₓ in which the transmittance of light having a wavelength of 365 nm is 90% and the composition ratio of nitrogen atoms.

In FIG. 7, the vertical axis represents the film thickness of a-SiNₓ when the transmittance of light having a wavelength of 365 nm is 90(%), and the horizontal axis represents the composition ratio x of nitrogen atoms. The film thickness of a-SiNₓ when the transmittance of light having a wavelength of 365 nm is 90(%) is calculated by using the absorption coefficient with respect to light having a wavelength of 365 nm illustrated in FIG. 5.

With reference to FIG. 7, the film thickness of a-SiNₓ when the transmittance is 90(%) is increased as the composition ratio x of nitrogen atoms is increased.

In order to set the transmittance of a-SiNₓ to a value less than 90(%), the film thickness of a-SiNₓ may be set to be greater than or equal to the film thickness illustrated in FIG. 7 for each composition ratio x. Therefore, in the photoelectric conversion element 100, the thickness of the non-crystalline thin film 202 is set to be greater than or equal to the film thickness illustrated in FIG. 7 for each composition ratio x. Accordingly, the non-crystalline thin film 202 (=a-SiNₓ) can efficiently absorb light having a wavelength less than or equal to 365 nm.

As described above, as the composition ratio x of nitrogen atoms of the a-SiNₓ becomes less than 0.85, the absorption coefficient of a-SiNₓ is rapidly increased. Thus, the range of the composition ratio x is preferably 0<x<0.85.

In a case where the composition ratio x is in the range of 0<x≦0.78, the film thickness in which the transmittance of a-SiNₓ is 90(%) is less than 100 nm. Meanwhile, in a case of using the a-SiNₓ as an antireflection coat, the film thickness of a-SiNₓ is generally set to approximately 100 nm.

As a result, by setting the film thickness of a-SiNₓ to, for example, 100 nm in a case where the composition ratio x is in the range of 0<x≦0.78, the non-crystalline thin film 202 functions as an absorption layer that absorbs ultraviolet light and as an antireflection coat. Therefore, the range of the composition ratio x is more preferably 0<x≦0.78. The a-SiNₓ (0<x≦0.78) of a film thickness in which the transmittance is greater than or equal to 90% and a-SiN_{y} (y>0.78) of an arbitrary film thickness may be combined to set a film thickness in which a desired reflectance is obtained and may be used as the non-crystalline thin film 202. Accordingly, the non-crystalline thin film 202 can efficiently absorb light having a wavelength less than or equal to 365 nm, and the reflectance thereof can be significantly decreased.

FIG. 8 is a diagram illustrating a relationship between the film thickness of a-SiNₓ in which the transmittance is 90% and the composition ratio of nitrogen atoms.

In FIG. 8, the vertical axis represents the film thickness of a-SiNₓ in which the transmittance is 90%, and the horizontal axis represents the composition ratio x of nitrogen atoms. Black rhombus shapes are experimental values illustrating the film thickness of a-SiNₓ in which the transmittance of light having a wavelength of 365 nm is 90%. Black quadrangles are experimental values illustrating the film thickness of a-SiNₓ in which the transmittance of light having a wavelength of 400 nm is 90%. A curve k1 is a curve that is fit by using Equation (1) below.

y1=a₀+a₁×x+a₂×x²+a₃×x³+a₄×x⁴ (1)

In Equation (1), the term y1 represents the film thickness of a-SiNₓ, and the terms a₀ to a₄ are coefficients. The coefficients a₀ to a₄ are such that a₀=2.5630206×10⁴, a₁=−1.5023931×10⁵, a₂=3.3006162×10⁵, a₃=−3.2201169×10⁵, and a₄=1.177911×10⁵.

A curve k2 is a curve that is fit by using Equation (2) below.

y2=b₀+b₂×x+b₂×x²+b₃×x³+b₄×x⁴ (2)

In Equation (2), the term y2 represents the film thickness of a-SiNₓ, and the terms b₀ to b₄ are coefficients. The coefficients b₀ to b₄ are such that b₀=7.2463535×10⁴, b₁=−4.2822151×10⁵, b₂=9.4846304×10⁵, b₃=−9.3314190×10⁵, and b₄=3.4429270×10⁵.

With reference to FIG. 8, the curve k1 well matches the experimental values illustrating the film thickness of a-SiNₓ in which the transmittance of light having a wavelength of 365 nm is 90%, and the curve k2 well matches the experimental values illustrating the film thickness of a-SiNₓ in which the transmittance of light having a wavelength of 400 nm is 90%.

In FIG. 8, a region REG that is surrounded by a dotted line is a region in which the transmittance of light having a wavelength less than or equal to 365 nm is less than or equal to 90% and the transmittance of light having a wavelength greater than or equal to 400 nm is greater than or equal to 90%.

That is, the region REG is a region that sufficiently absorbs light having a wavelength less than or equal to 365 nm and sufficiently transmits light having a wavelength greater than or equal to 400 nm.

Therefore, by forming the non-crystalline thin film 202 configured of a-SiNₓ that has the relationship between the composition ratio x and the film thickness in the region REG, degradation of the non-crystalline thin film 201 can be suppressed, thereby obtaining a high short-circuit current.

The number of photons included in the solar spectrum (AM1.5) in wavelengths greater than or equal to 400 nm occupies approximately 95% of the photons included in the solar spectrum (AM1.5). Thus, a high output current can be obtained by increasing the transmittance of light having a wavelength of 400 nm.

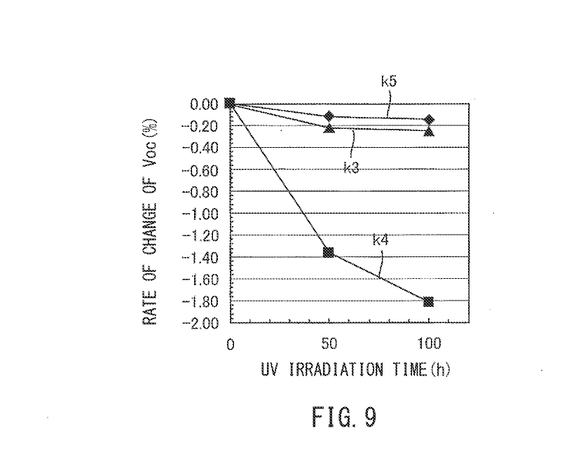

FIG. 9 is a diagram illustrating a result of a light irradiation test for the photoelectric conversion element 100. In FIG. 9, the vertical axis represents the rate of change of an open-circuit voltage (Voc), and the horizontal axis represents an ultraviolet light (UV) irradiation time. A curve k3 illustrates a result of a light irradiation test for a photoelectric conversion element in a case of using a-SiNₓ (x=0.78) having a high absorption coefficient as the non-crystalline thin film 202. A curve k4 illustrates a result of a light irradiation test for a photoelectric conversion element in a case of using a-SiNₓ (x=1.0) having a low absorption coefficient as the non-crystalline thin film 202. A curve k5 illustrates temporal changes in a photoelectric conversion element that is not irradiated with ultraviolet light (UV). The photoelectric conversion element of the curve k4 and the photoelectric conversion element of the curve k5 are manufactured under the same condition except for the presence of ultraviolet light irradiation.

The rate of change of the open-circuit voltage (Voc) is obtained by [(Voc after ultraviolet light irradiation)−(Voc before ultraviolet light irradiation)]/(Voc before ultraviolet light irradiation). Therefore, it is indicated that the open-circuit voltage (Voc) is significantly decreased as the absolute value of the rate of change is increased.

With reference to FIG. 9, in a case of using a-SiNₓ having a high absorption coefficient as the non-crystalline thin film 202, the rate of change of the open-circuit voltage (Voc) is −0.25(%) after 100 hours of UV light irradiation (refer to the curve k3).

Meanwhile, in a case of using a-SiNₓ having a low absorption coefficient as the non-crystalline thin film 202, the rate of change of the open-circuit voltage (Voc) is −1.80(%) after 100 hours of UV light irradiation (refer to the curve k4).

In a case where the photoelectric conversion element manufactured by the same manufacturing method as the photoelectric conversion element of the curve k4 is not irradiated with UV light, the rate of change of the open-circuit voltage (Voc) is −0.14(%) after the elapse of 100 hours (curve k5). Therefore, it is understood that a decrease of the open-circuit voltage (Voc) illustrated by the curve k4 is insignificantly affected by temporal changes and is mainly attributable to UV light irradiation.

As such, by using a-SiNₓ having a high absorption coefficient as the non-crystalline thin film 202, it is proven that the rate of decrease of the open-circuit voltage (Voc) after UV light irradiation can be significantly decreased.

The reason why a decrease of the open-circuit voltage (Voc) is suppressed is considered to be suppression of an increase of a defect density in the non-crystalline thin film 201 (=a-Si) and in the interface between the non-crystalline thin film 201 (=a-Si) and the n-type monocrystalline silicon substrate 1 since the non-crystalline thin film 202 configured of a-SiNₓ having a high absorption coefficient absorbs ultraviolet light, thereby decreasing the proportion of ultraviolet light reaching the a-Si constituting the non-crystalline thin film 201 and rendering cleavage of the Si—H bonds in the a-Si unlikely.

As described above, by stacking the non-crystalline thin film 201 (=a-Si) and the non-crystalline thin film 202 (=a-SiNₓ (0<x<0.85)) in order on the surface on the light incident side of the n-type monocrystalline silicon substrate 1, it is understood that a decrease of the open-circuit voltage (Voc) of the photoelectric conversion element 100 due to UV light irradiation can be suppressed.

Therefore, by disposing the non-crystalline thin film 2 on the surface on the light incident side of the n-type monocrystalline silicon substrate 1, photodegradation of the photoelectric conversion element 100 can be suppressed.

In the photoelectric conversion element 100, if the photoelectric conversion element 100 is irradiated with sunlight from the non-crystalline thin film 2 side thereof, the non-crystalline thin film 202 of the non-crystalline thin film 2 absorbs at least a part of light having a wavelength less than or equal to 365 nm and guides the remaining light into the n-type monocrystalline silicon substrate 1 through the non-crystalline thin film 201. Then, electrons and electron holes are optically excited in the n-type monocrystalline silicon substrate 1. Since the non-crystalline thin film 202 absorbs at least a part of light having a wavelength less than or equal to 365 nm, the Si—H bonds in the a-Si constituting the non-crystalline thin film 201 are unlikely to be cleaved, and an increase the defect density of the non-crystalline thin film 201 is suppressed.

The optically excited electrons and electron holes, even if diffused to the non-crystalline thin film 2 side of the n-type monocrystalline silicon substrate 1, are unlikely to recombine due to the passivation effect of the n-type monocrystalline silicon substrate 1 achieved by the non-crystalline thin film 201 and are likely to be diffused to the p-type non-crystalline films 31 to 3m and n-type non-crystalline films 41 to 4m-1 side of the n-type monocrystalline silicon substrate 1.

The electrons and electron holes that are diffused toward the p-type non-crystalline films 31 to 3m and n-type non-crystalline films 41 to 4m-1 are separated by an internal electric field caused by the p-type non-crystalline films 31 to 3m/n-type monocrystalline silicon substrate 1 (=p-n junction). The electron holes reach the electrodes 51 to 5m through the i-type non-crystalline thin films 11 to 1m and the p-type non-crystalline films 31 to 3m, and the electrons reach the electrodes 61 to 6m-1 through the i-type non-crystalline thin films 21 to 2m-1 and the n-type non-crystalline films 41 to 4m-1.

The electrons that reach the electrodes 61 to 6m-1 reach the electrodes 51 to 5m through loads connected between the electrodes 51 to 5m and the electrodes 61 to 6m-1 and recombine with the electron holes.

As such, the photoelectric conversion element 100 is a back contact type photoelectric conversion element in which electrons and electron holes that are optically excited in the n-type monocrystalline silicon substrate 1 are obtained from the rear surface (=surface on the opposite side to the surface of the n-type monocrystalline silicon substrate 1 on which the non-crystalline thin film 2 is formed) of the n-type monocrystalline silicon substrate 1.

In the photoelectric conversion element 100, since the non-crystalline thin film 2 is arranged in contact with the surface on the light incident side of the n-type monocrystalline silicon substrate 1, as described above, the non-crystalline thin film 202 absorbs at least a part of light having a wavelength corresponding to energy greater than or equal to the bond energy of 3.4 eV between hydrogen and silicon that is an atom other than a hydrogen atom constituting the non-crystalline thin film 202, and the Si—H bonds in the non-crystalline thin film 201 (=a-Si) are unlikely to be cleaved. As a result, even if the photoelectric conversion element 100 is irradiated with ultraviolet light, a decrease of the open-circuit voltage (Voc) is suppressed, and photodegradation of the photoelectric conversion element 100 can be suppressed.

The photoelectric conversion element 100 has a structure in which the n-type monocrystalline silicon substrate 1 is interposed between the non-crystalline thin film 201 (=a-Si) and the i-type non-crystalline thin films 11 to 1m and 21 to 2m-1 (=i-type a-Si). Thus, curvature of the n-type monocrystalline silicon substrate 1 can be prevented. In addition, the rear surface of the n-type monocrystalline silicon substrate 1 can be passivated.

The non-crystalline thin film 201 (=a-Si) and the i-type non-crystalline thin films 11 to 1m and 21 to 2m-1 (=i-type a-Si) are formed by plasma CVD. Thus, in the manufacturing process of the photoelectric conversion element 100, thermal strains exerted on the n-type monocrystalline silicon substrate 1 can be prevented, and a decrease of carrier characteristics can be suppressed in the n-type monocrystalline silicon substrate 1.

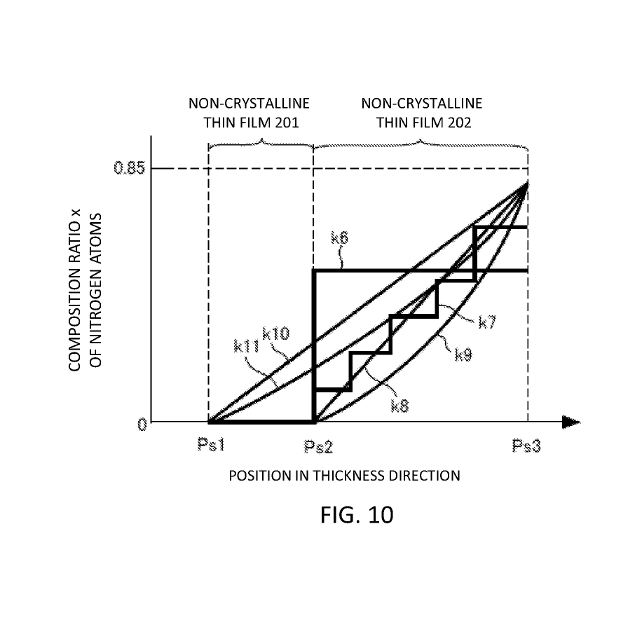

FIG. 10 is a diagram illustrating a distribution of the composition ratio of nitrogen atoms in a thickness direction. In FIG. 10, the vertical axis represents the composition ratio x of nitrogen atoms, and the horizontal axis represents a position in the thickness direction. A position Ps1 corresponds to the interface between the n-type monocrystalline silicon substrate 1 and the non-crystalline thin film 201. A position Ps2 corresponds to the interface between the non-crystalline thin film 201 and the non-crystalline thin film 202. A position Ps3 corresponds to the surface on the light incident side of the non-crystalline thin film 202.

With reference to FIG. 10, in a case where the non-crystalline thin film 201 is configured of a-Si and the non-crystalline thin film 202 is configured of a-SiNₓ (0<x<0.85), the composition ratio x of nitrogen atoms is distributed in accordance with a curve k6 in the non-crystalline thin film 2. That is, the composition ratio x is 0 in the region corresponding to a-Si from the position Ps1 to the position Ps2, and the composition ratio x is constant in the range of 0<x<0.85 in the region corresponding to a-SiNₓ from the position Ps2 to the position Ps3. In this case, the non-crystalline thin film 2 has a two-layer structure.

The composition ratio x of nitrogen atoms may be distributed in accordance with a curve k7 in the non-crystalline thin film 2. That is, the composition ratio x is “0” in the region corresponding to a-Si from the position Ps1 to the position Ps2, and the composition ratio x is stepwise increased from the position Ps2 toward the position Ps3 in the range of 0<x<0.85 in the region corresponding to a-SiNₓ from the position Ps2 to the position Ps3. In this case, the non-crystalline thin film 2 has a multilayer structure having more than two layers. The thickness in which the composition ratio x is constant may be the same or different among a plurality of steps. The proportion of the composition ratio x increased may be the same or different among the plurality of steps. The number of the plurality of steps is not limited to the number of steps of the curve k7 and may be two or more.

The composition ratio x of nitrogen atoms may be distributed in accordance with a curve k8 in the non-crystalline thin film 2. That is, the composition ratio x is “0” in the region corresponding to a-Si from the position Ps1 to the position Ps2, and the composition ratio x is straight linearly increased from the position Ps2 toward the position Ps3 in the range of 0<x<0.85 in the region corresponding to a-SiNₓ from the position Ps2 to the position Ps3. Also in this case, the non-crystalline thin film 2 has a two-layer structure.

The composition ratio x of nitrogen atoms may be distributed in accordance with a curve k9 in the non-crystalline thin film 2. That is, the composition ratio x is “0” in the region corresponding to a-Si from the position Ps1 to the position Ps2, and the composition ratio x is non-linearly increased from the position Ps2 toward the position Ps3 in the range of 0<x<0.85 in the region corresponding to a-SiNₓ from the position Ps2 to the position Ps3. Also in this case, the non-crystalline thin film 2 has a two-layer structure. The curve k9 is a convex downward curve but is not limited thereto and may be a convex upward curve and generally may be non-linear.

The composition ratio x of nitrogen atoms may be distributed in accordance with a straight line k10 in the non-crystalline thin film 2. That is, the composition ratio x is straight linearly increased from “0” from the position Ps1 toward the position Ps3 in the range of 0<x<0.85. The proportion of the composition ratio x increased is arbitrary.

The composition ratio x of nitrogen atoms may be distributed in accordance with a curve k11 in the non-crystalline thin film 2. That is, the composition ratio x is non-linearly increased from “0” from the position Ps1 toward the position Ps3 in the range of 0<x<0.85. The curve k11 is a convex downward curve but is not limited thereto and may be a convex upward curve and generally may be non-linear. The inclination of the curve k11 at the position Ps1 is preferably “0”.

In a case where the composition ratio x is distributed in accordance with either the straight line k10 or the curve k11, the composition ratio x is “0” at the position Ps1 corresponding to the interface between the n-type monocrystalline silicon substrate 1 and the non-crystalline thin film 201. Thus, the surface on the light incident side of the n-type monocrystalline silicon substrate 1 is in contact with a-Si. Therefore, the non-crystalline thin film 2 passivates the surface on the light incident side of the n-type monocrystalline silicon substrate 1.

In a case where the composition ratio x is distributed in accordance with the curves k6 to k9 and k11 and the straight line k10, the composition ratio x at the position Ps3 may be the same or different among the curves k6 to k9 and k11 and the straight line k10.

As such, in the embodiment of the invention, the composition ratio x of nitrogen atoms in the non-crystalline thin film 2 changes in accordance with various types of curves k6 to k9 and k11 and the straight line k10 illustrated in FIG. 10. As a result, the non-crystalline thin film 2 has at least a two-layer structure.

In a case where the non-crystalline thin film 2 has at least a two-layer structure, that is, in a case where the composition ratio x of nitrogen atoms is stepwise increased, absorption of ultraviolet light can suppress an increase of defects in the non-crystalline thin film 201, and the reflectance can be decreased on the surface on the light incident side of the photoelectric conversion element 100. The reason is that a refractive index distribution of the non-crystalline thin film 2 is stepwise increased from the light incident side toward the n-type monocrystalline silicon substrate 1 side of the non-crystalline thin film 2 and a refractive index distribution that reduces the reflectance can be easily realized.

In a case where the composition ratio x of nitrogen atoms is increased either straight linearly or non-linearly, the refractive index of the non-crystalline thin film 2 is distributed smoothly from the light incident side toward the n-type monocrystalline silicon substrate 1. Therefore, the reflectance of incident light can be further decreased than in a case where the composition ratio of nitrogen atoms is stepwise distributed. In addition, the non-crystalline thin film 2 can be easily formed by changing the flow rate of the material gas of nitrogen atoms.

While FIG. 10 illustrates only a case where the composition ratio x of nitrogen atoms in the non-crystalline thin film 202 is increased in a direction from the position Ps2 toward the position Ps3, the composition ratio x is not limited thereto and may be distributed in any form provided that the non-crystalline thin film 201 is disposed or an absorption layer is disposed further on the light incident side from the region of composition ratio x=0 starting from the position Ps1 (for example, the region of 0<x<0.85). For example, the composition ratio x may be the greatest at the position Ps2, or the composition ratio x may be the maximum value between the position Ps2 and the position Ps3.

While the photoelectric conversion element 100 is described above as including the n-type monocrystalline silicon substrate 1, in the first embodiment, the photoelectric conversion element 100 is not limited thereto and may include any of an n-type polycrystalline silicon substrate, a p-type monocrystalline silicon substrate, and a p-type polycrystalline silicon substrate instead of the n-type monocrystalline silicon substrate 1 and generally may include a crystalline silicon substrate.

In a case where the photoelectric conversion element 100 includes an n-type polycrystalline silicon substrate, the n-type polycrystalline silicon substrate has a thickness of 50 μm to 300 μm and preferably has a thickness of 80 μm to 200 μm. The n-type polycrystalline silicon substrate has a resistivity of 0.1 Ω·cm to 10 Ω·cm. The surface on the light incident side of the n-type polycrystalline silicon substrate is, for example, rendered rough by dry etching.

In a case where the photoelectric conversion element 100 includes a p-type monocrystalline silicon substrate or a p-type polycrystalline silicon substrate, the p-type monocrystalline silicon substrate or the p-type polycrystalline silicon substrate has a thickness of 50 μm to 300 μm and preferably has a thickness of 80 μm to 200 μm. The p-type monocrystalline silicon substrate or the p-type polycrystalline silicon substrate has a resistivity of 0.1 Ω·cm to 10 Ω·cm. The surface on the light incident side of the p-type monocrystalline silicon substrate is texturized by the same method as the method in Process (b) of FIG. 2, and the surface on the light incident side of the p-type polycrystalline silicon substrate is, for example, rendered rough by dry etching.

In a case where the photoelectric conversion element 100 includes a p-type monocrystalline silicon substrate or a p-type polycrystalline silicon substrate, the area occupancy that is the proportion of the area of the p-type monocrystalline silicon substrate or the p-type polycrystalline silicon substrate occupied by the area of all of the n-type non-crystalline thin films 41 to 4m-1 is 50% to 95%, and the area occupancy that is the proportion of the area of the p-type monocrystalline silicon substrate or the p-type polycrystalline silicon substrate occupied by the area of all of the p-type non-crystalline thin films 31 to 3m is 5% to 50%.

As such, the reason why the area occupancy made by the n-type non-crystalline thin films 41 to 4m-1 is rendered greater than the area occupancy made by the p-type non-crystalline thin films 31 to 3m is that optically excited electrons and electron holes are likely to be separated by p-n junctions (n-type non-crystalline thin films 41 to 4m-1/p-type monocrystalline silicon substrate (or p-type polycrystalline silicon substrate)) in the p-type monocrystalline silicon substrate or the p-type polycrystalline silicon substrate and that the ratio of optically excited electrons and electron holes contributing to power generation is increased.

While the non-crystalline thin film 201 of the non-crystalline thin film 2 is described as being configured of a-Si and the non-crystalline thin film 202 is described as being configured of a-SiNₓ (0<x<0.85; further preferably, 0<x≦0.78) in the photoelectric conversion element 100, in the first embodiment, the non-crystalline thin film 201 and the non-crystalline thin film 202 are not limited thereto. The non-crystalline thin film 201 may be configured of any of a-Sige and a-Ge, and the non-crystalline thin film 202 may be configured of any of a-SiO and a-SiON. A combination of the material constituting the non-crystalline thin film 201 and the material constituting the non-crystalline thin film 202 may be any combination provided that the combination causes the optical band gap of the non-crystalline thin film 202 to be greater than the optical band gap of the non-crystalline thin film 201. In this case, the combination ratio of oxygen atoms and/or nitrogen atoms in a-SiO or a-SiON constituting the non-crystalline thin film 202 is distributed in accordance with any of the curves k6 to k9 and k11 and the straight line k10 illustrated in FIG. 10. The range of the composition ratio of oxygen atoms and/or nitrogen atoms is determined to be a range that resides less than the composition ratio immediately before a discontinuous increase of the rate of change of the absorption coefficient for light of 365 nm with respect to the composition ratio. In FIG. 5, the rate of change of the absorption coefficient with respect to the composition ratio when the composition ratio x is 0<x<0.85 is discontinuously increased in contrast to the rate of change of the absorption coefficient with respect to the composition ratio when the composition ratio x is greater than or equal to 0.85. Therefore, the range of the composition ratio x is determined to be 0<x<0.85 that is the range residing less than the composition ratio (=0.85) immediately before a discontinuous increase of the rate of change of the absorption coefficient with respect to the composition ratio. Preferably, the range of the composition ratio x is determined to be <x≦0.78 that is the range residing less than or equal to the composition ratio at which the transmittance of light having a wavelength of 365 nm is less than or equal to 90% in a film thickness of 100 nm. Therefore, also in a case where the non-crystalline thin film 202 is configured of any of a-SiO and a-SiON, the composition ratio of oxygen atoms and/or nitrogen atoms is determined in the same manner. Thus, the above effect can be accomplished also in a case where the non-crystalline thin film 202 is configured of any of a-SiO and a-SiON.

The a-Si, a-SiGe, or a-Ge constituting the non-crystalline thin film 201 may include dopants such as a P atom and a B atom, and the a-SiN, a-SiO, or a-SiON constituting the non-crystalline thin film 202 may include dopants such as a P atom and a B atom. The reason is that dopant atoms may be mixed into the a-Si, a-SiGe, or a-Ge in a case of manufacturing the photoelectric conversion element 100 by plasma CVD using one reaction chamber.

The a-Si, a-SiGe, or a-Ge constituting the non-crystalline thin film 201 is preferably hydrogenated amorphous silicon (a-Si:H) that includes hydrogen atoms, hydrogenated amorphous silicon germanium (a-SiGe:H) that includes hydrogen atoms, or hydrogenated germanium (a-Ge:H) that includes hydrogen atoms. The a-SiN, a-SiO, or a-SiON constituting the non-crystalline thin film 202 is preferably hydrogenated amorphous silicon nitride (a-SiN:H) that includes hydrogen atoms, hydrogenated amorphous silicon oxide (a-SiO:H) that includes hydrogen atoms, or hydrogenated silicon oxynitride (a-SiON:H) that includes hydrogen atoms.

As such, by configuring the non-crystalline thin films 201 and 202 as non-crystalline thin films that include hydrogen atoms, defects in the non-crystalline thin films 201 and 202 can be reduced, and passivation characteristics of the n-type monocrystalline silicon substrate 1 can be further improved.

While the non-crystalline thin film 202 is described as being disposed in contact with the non-crystalline thin film 201, in the first embodiment, the non-crystalline thin film 202 is not limited thereto and is not necessarily disposed in contact with the non-crystalline thin film 201 and may be disposed further on the light incident side than the non-crystalline thin film 201. Therefore, for example, another non-crystalline thin film may be interposed between the non-crystalline thin film 201 and the non-crystalline thin film 202.

Since the non-crystalline thin film 202 is configured of a-SiN, a-SiO, a-SiON, or the like as described above and the composition ratio of nitride atoms and/or oxygen atoms in the non-crystalline thin film 2 is distributed in accordance with any of the curves k6 to k9 and k11 and the straight line k10 illustrated in FIG. 10, generally, the non-crystalline thin film 2 may include desired atoms for setting the optical band gap of an absorption layer (=a-SiN, a-SiO, or a-SiON) to an optical band gap greater than the optical band gap of a passivation film (=a-Si), and the composition ratio of the desired atoms may be increased from the crystalline silicon substrate side end portion of the non-crystalline thin film 2 toward the end portion on the light incident side of the non-crystalline thin film 2. In this case, the absorption layer (=a-SiN, a-SiO, or a-SiON) is arranged further on the light incident side than the passivation film (=a-Si) and absorbs ultraviolet light.

While the i-type non-crystalline thin films 11 to 1m and 21 to 2m-1 are described as being configured of i-type a-Si in the photoelectric conversion element 100, in the first embodiment, the i-type non-crystalline thin films 11 to 1m and 21 to 2m-1 are not limited thereto and may be configured of i-type a-SiGe or i-type a-Ge.

While the p-type non-crystalline thin films 31 to 3m are described as being configured of p-type a-Si in the photoelectric conversion element 100, in the first embodiment, the p-type non-crystalline thin films 31 to 3m are not limited thereto and may be configured of any of p-type a-SiC, p-type a-SiO, p-type a-SiN, p-type a-SiCN, p-type a-SiGe, and p-type a-Ge.

While the n-type non-crystalline thin films 41 to 4m-1 are described as being configured of n-type a-Si in the photoelectric conversion element 100, in the first embodiment, the n-type non-crystalline thin films 41 to 4m-1 are not limited thereto and may be configured of any of n-type a-SiC, n-type a-SiO, n-type a-SiN, n-type a-SiCN, n-type a-SiGe, and n-type a-Ge.

That is, in the photoelectric conversion element 100, each of the i-type non-crystalline thin films 11 to 1m and 21 to 2m-1, the p-type non-crystalline thin films 31 to 3m, and the n-type non-crystalline thin films 41 to 4m-1 may be configured of any material illustrated in Table 1.

TABLE 1

| i-type non- | | |
|---|---|---|
| crystalline thin | p-type non- | n-type non- |
| films 11 to 1m and | crystalline thin | crystalline thin |
| 21 to 2m−1 | films 31 to 3m | films 41 to 4m−1 |
| i-type a-Si | p-type a-SiC | n-type a-SiC |
| i-type a-SiGe | p-type a-SiO | n-type a-SiO |
| i-type a-Ge | p-type a-SiN | n-type a-SiN |
| | p-type a-SiCN | n-type a-SiCN |
| | p-type a-Si | n-type a-Si |
| | p-type a-SiGe | n-type a-SiGe |
| | p-type a-Ge | n-type a-Ge |

In this case, the i-type a-SiGe is formed by the above plasma CVD with an SiH₄ gas and a germane (GeH₄) gas as material gases. The i-type a-Ge is formed by the above plasma CVD with a GeH₄ gas as a material gas.

The p-type a-SiC is formed by the above plasma CVD with an SiH₄ gas, a methane (CH₄) gas, and a B₂H₆ gas as material gases. The p-type a-SiO is formed by the above plasma CVD with an SiH₄ gas, an oxygen (O₂) gas, and a B₂H₆ gas as material gases. The p-type a-SiN is formed by the above plasma CVD with an SiH₄ gas, an NH₃ gas, and a B₂H₆ gas as material gases. The p-type a-SiCN is formed by the above plasma CVD with an SiH₄ gas, a CH₄ gas, an NH₃ gas, and a B₂H₆ gas as material gases. The p-type a-SiGe is formed by the above plasma CVD with an SiH₄ gas, a GeH₄ gas, and a B₂H₆ gas as material gases. The p-type a-Ge is formed by the above plasma CVD with a GeH₄ gas and a B₂H₆ gas as material gases.

The n-type a-SiC is formed by the above plasma CVD with an SiH₄ gas, a CH₄ gas, and a PH₃ gas as material gases. The n-type a-SiO is formed by the above plasma CVD with an SiH₄ gas, an O₂ gas, and a PH₃ gas as material gases. The n-type a-SiN is formed by the above plasma CVD with an SiH₄ gas, an NH₃ gas, and a PH₃ gas as material gases. The n-type a-SiCN is formed by the above plasma CVD with an SiH₄ gas, a CH₄ gas, an NH₃ gas, and a PH₃ gas as material gases. The n-type a-SiGe is formed by the above plasma CVD with an SiH₄ gas, a GeH₄ gas, and a PH₃ gas as material gases. The n-type a-Ge is formed by the above plasma CVD with a GeH₄ gas and a PH₃ gas as material gases.

While a texture structure is described above as being formed on the surface on the light incident side of the n-type monocrystalline silicon substrate 1, in the first embodiment, the texture structure is not limited thereto and may be also formed on the surface of the n-type monocrystalline silicon substrate 1 on the opposite side to the light incident side.

### Second Embodiment

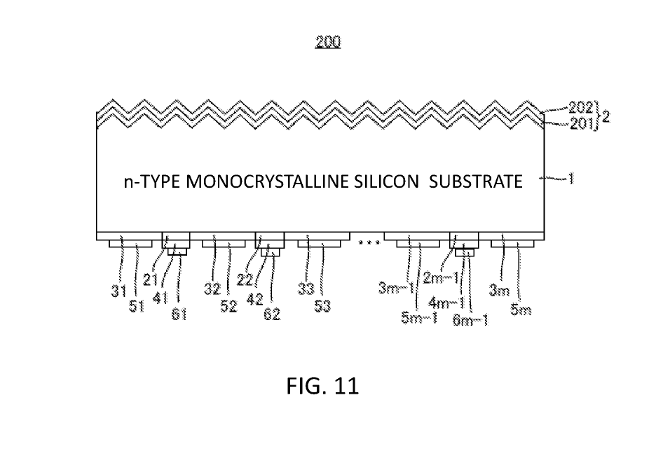

FIG. 11 is a sectional view illustrating a configuration of a photoelectric conversion element according to a second embodiment. With reference to FIG. 11, a photoelectric conversion element 200 according to the second embodiment is the same as the photoelectric conversion element 100 except that the i-type non-crystalline thin films 11 to 1m of the photoelectric conversion element 100 illustrated in FIG. 1 are removed.

In the photoelectric conversion element 200, the p-type non-crystalline thin films 31 to 3m are arranged in contact with the n-type monocrystalline silicon substrate 1.

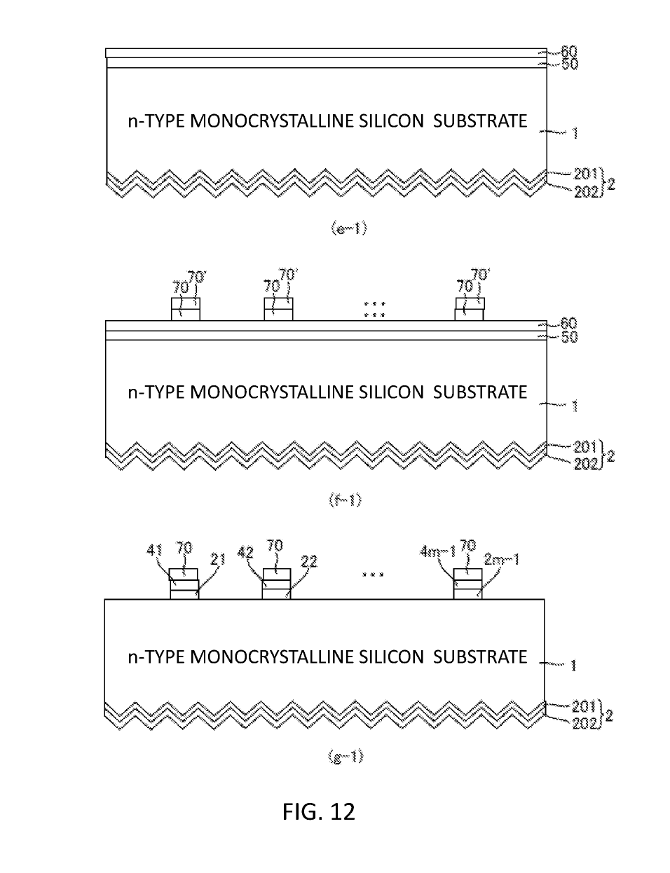

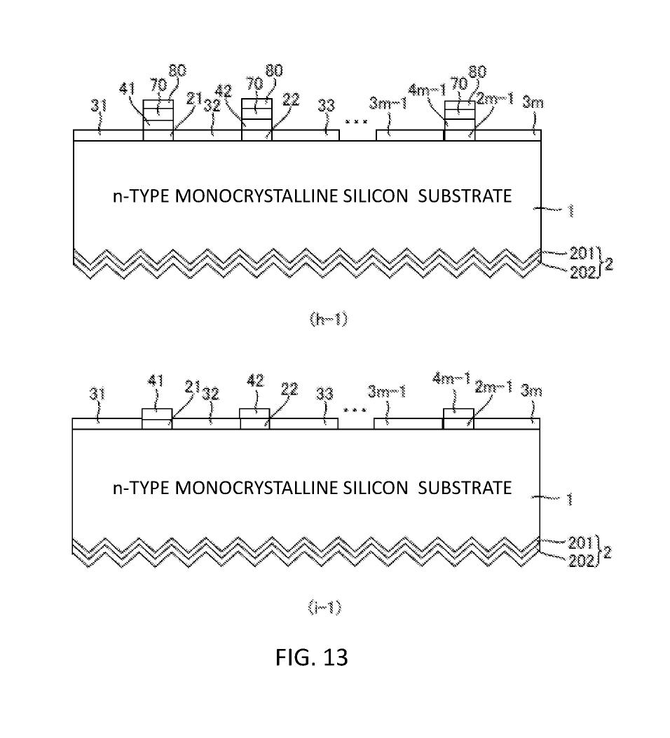

FIG. 12 and FIG. 13 are partial process charts for manufacturing the photoelectric conversion element 200 illustrated in FIG. 11.

The photoelectric conversion element 200 is manufactured in accordance with a process in which Process (e) to Process (i) of Process (a) to Process (k) illustrated in FIG. 2 to FIG. 4 are respectively replaced by Process (e-1) to Process (i-1) illustrated in FIG. 12 and FIG. 13.

If manufacturing of the photoelectric conversion element 200 is started, above Process (a) to Process (d) are performed in order.

After Process (d), the non-crystalline thin film 2/n-type monocrystalline silicon substrate 1 is withdrawn from the plasma CVD apparatus, and the non-crystalline thin film 2/n-type monocrystalline silicon substrate 1 is put into the plasma CVD apparatus in such a manner that a thin film can be accumulated on the rear surface (surface on the opposite side to the surface on which the non-crystalline thin film 2 is formed) of the n-type monocrystalline silicon substrate 1.

An i-type non-crystalline thin film 50 that is configured of i-type a-Si is accumulated on the n-type monocrystalline silicon substrate 1 under the same condition as the manufacturing condition in Process (e) of FIG. 3. Then, an SiH₄ gas and a PH₃ gas are caused to flow into the reaction chamber. The pressure of the reaction chamber is set to, for example, 30 Pa to 600 Pa, and the RF power supply applies the RF power to the parallel plate electrodes through the matcher. Accordingly, an n-type non-crystalline thin film 60 that is configured of n-type a-Si is accumulated on the i-type non-crystalline thin film 50 (refer to Process (e-1) of FIG. 12).

Then, an SiH₄ gas and an NH₃ gas are caused to flow into the reaction chamber. The pressure of the reaction chamber is set to, for example, 30 Pa to 600 Pa, and the RF power supply applies the RF power to the parallel plate electrodes through the matcher. Accordingly, a cladding layer that is configured of a-SiN is formed on the n-type non-crystalline thin film 60. The cladding layer may be configured of silicon oxide. A resist pattern is formed on the cladding layer by photolithography, and then, the cladding layer in opening portions of the resist is etched by using hydrofluoric acid or the like to form cladding layers 70 that are arranged at desired intervals on the n-type non-crystalline thin film 60 (refer to Process (f-1) of FIG. 12).

The i-type non-crystalline thin film 50 and the n-type non-crystalline thin film 60 are etched by dry etching or wet etching with resists 70′ and the cladding layers 70 as a mask to form the i-type non-crystalline thin films 21 to 2m-1 and the n-type non-crystalline thin films 41 to 4m-1 (refer to Process (g-1) of FIG. 12). Then, the resists 70′ are removed.

If the i-type non-crystalline thin films 21 to 2m-1 and the n-type non-crystalline thin films 41 to 4m-1 are formed, the n-type non-crystalline thin films 41 to 4m-1 side of the n-type non-crystalline thin films 41 to 4m-1/i-type non-crystalline thin films 21 to 2m-1/n-type monocrystalline silicon substrate 1/non-crystalline thin film 2 is cleaned with hydrofluoric acid, and the n-type non-crystalline thin films 41 to 4m-1/i-type non-crystalline thin films 21 to 2m-1/n-type monocrystalline silicon substrate 1/non-crystalline thin film 2 is put into the plasma CVD apparatus.

An SiH₄ gas and a B₂H₆ gas are caused to flow into the reaction chamber. The pressure of the reaction chamber is set to, for example, 30 Pa to 600 Pa, and the temperature of the substrate is set to, for example, 100° C. to 300° C. The RF power supply applies the RF power to the parallel plate electrodes through the matcher. Accordingly, the p-type non-crystalline thin films 31 to 3m configured of p-type a-Si are accumulated on the n-type monocrystalline silicon substrate 1 in contact with the n-type monocrystalline silicon substrate 1, and p-type non-crystalline thin films 80 that are configured of p-type a-Si are accumulated on the cladding layers 70 (refer to Process (h-1) of FIG. 13).

If the p-type non-crystalline thin films 31 to 3m are accumulated on the n-type monocrystalline silicon substrate 1, the non-crystalline thin film 2/n-type monocrystalline silicon substrate 1/i-type non-crystalline thin films 21 to 2m-1/n-type non-crystalline thin films 41 to 4m-1 and p-type non-crystalline thin films 31 to 3m/cladding layers 70/p-type non-crystalline thin films 80 are withdrawn from the plasma CVD apparatus.

The cladding layers 70 are removed by etching using, for example, hydrofluoric acid. Accordingly, the p-type non-crystalline thin films 80 are removed by being lift-off (refer to Process (i-1) of FIG. 13).

Then, Process (j) illustrated in FIG. 4 is performed. The electrodes 51 to 5m are respectively formed on the p-type non-crystalline thin films 31 to 3m, and the electrodes 61 to 6m-1 are respectively formed on the n-type non-crystalline thin films 41 to 4m-1. Accordingly, the photoelectric conversion element 200 is completed.

The power generation mechanism of the photoelectric conversion element 200 is the same as the power generation mechanism of the above photoelectric conversion element 100. Thus, the photoelectric conversion element 200 is also a back contact type photoelectric conversion element.

Also in the photoelectric conversion element 200, the non-crystalline thin film 2 is formed in contact with the surface on the light incident side of the n-type monocrystalline silicon substrate 1.

Therefore, an absorption layer (non-crystalline thin film 202) absorbs at least a part of light having a wavelength corresponding to energy greater than or equal to the bond energy of 3.4 eV between hydrogen and silicon that is an atom other than a hydrogen atom constituting the non-crystalline thin film 202, and photodegradation of the photoelectric conversion element 200 can be reduced.

While a texture structure is described above as being formed on the surface on the light incident side of the n-type monocrystalline silicon substrate 1, in the second embodiment, the texture structure is not limited thereto and may be also formed on the surface of the n-type monocrystalline silicon substrate 1 on the opposite side to the light incident side.

Other descriptions in the second embodiment are the same as the descriptions in the first embodiment.

### Third Embodiment

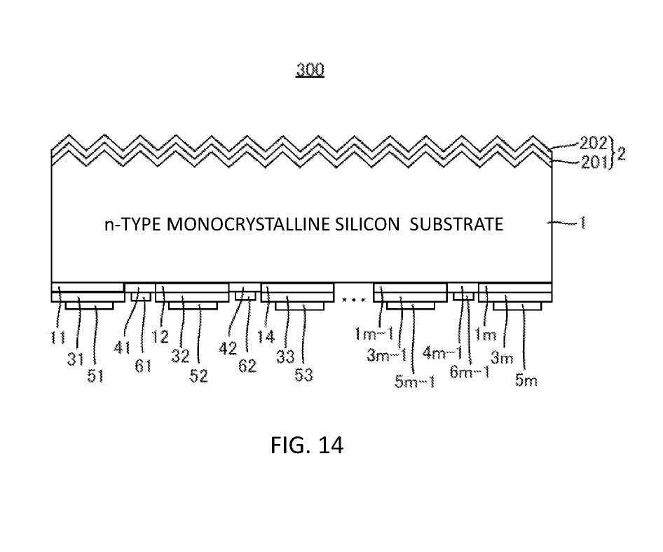

FIG. 14 is a sectional view illustrating a configuration of a photoelectric conversion element according to a third embodiment. With reference to FIG. 14, a photoelectric conversion element 300 according to the third embodiment is the same as the photoelectric conversion element 100 except that the i-type non-crystalline thin films 21 to 2m-1 of the photoelectric conversion element 100 illustrated in FIG. 1 are removed.

In the photoelectric conversion element 300, the n-type non-crystalline thin films 41 to 4m-1 are arranged in contact with the n-type monocrystalline silicon substrate 1.

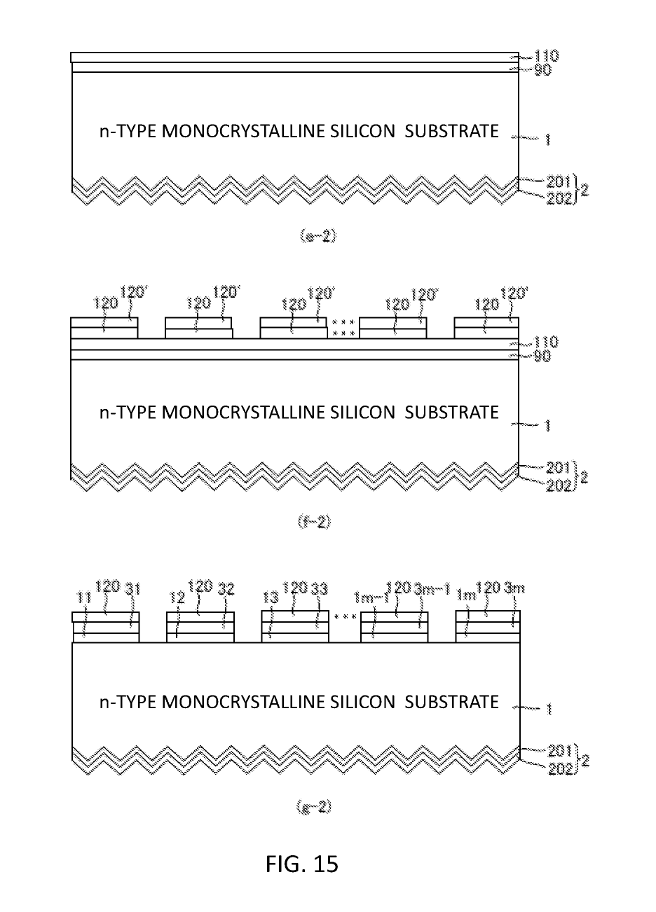

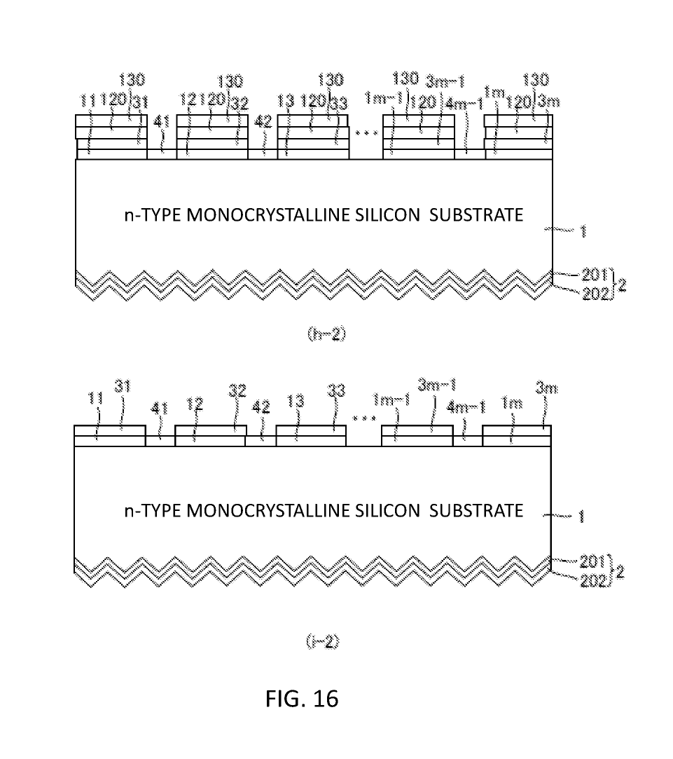

FIG. 15 and FIG. 16 are partial process charts for manufacturing the photoelectric conversion element 300 illustrated in FIG. 14.

The photoelectric conversion element 300 is manufactured in accordance with a process in which Process (e) to Process (i) of Process (a) to Process (k) illustrated in FIG. 2 to FIG. 4 are respectively replaced by Process (e-2) to Process (i-2) illustrated in FIG. 15 and FIG. 16.

If manufacturing of the photoelectric conversion element 300 is started, above Process (a) to Process (d) are performed in order.

After Process (d), the non-crystalline thin film 2/n-type monocrystalline silicon substrate 1 is withdrawn from the plasma CVD apparatus, and the non-crystalline thin film 2/n-type monocrystalline silicon substrate 1 is put into the plasma CVD apparatus in such a manner that a thin film can be accumulated on the rear surface (surface on the opposite side to the surface on which the non-crystalline thin film 2 is formed) of the n-type monocrystalline silicon substrate 1.

An i-type non-crystalline thin film 90 that is configured of i-type a-Si is accumulated on the n-type monocrystalline silicon substrate 1 under the same condition as the manufacturing condition in Process (e) of FIG. 3. Then, an SiH₄ gas and a B₂H₆ gas are caused to flow into the reaction chamber. The pressure of the reaction chamber is set to, for example, 30 Pa to 600 Pa, and the RF power supply applies the RF power to the parallel plate electrodes through the matcher. Accordingly, a p-type non-crystalline thin film 110 that is configured of p-type a-Si is accumulated on the i-type non-crystalline thin film 90 (refer to Process (e-2) of FIG. 15).

Then, an SiH₄ gas and an NH₃ gas are caused to flow into the reaction chamber. The pressure of the reaction chamber is set to, for example, 30 Pa to 600 Pa, and the RF power supply applies the RF power to the parallel plate electrodes through the matcher. Accordingly, a cladding layer that is configured of a-SiN is formed on the p-type non-crystalline thin film 110. The cladding layer may be configured of silicon oxide. A resist pattern is formed on the cladding layer by photolithography, and then, the cladding layer in opening portions of the resist is etched by using hydrofluoric acid or the like to form cladding layers 120 that are arranged at desired intervals on the p-type non-crystalline thin film 110 (refer to Process (f-2) of FIG. 15).

The i-type non-crystalline thin film 90 and the p-type non-crystalline thin film 110 are etched by dry etching or wet etching with resists 120′ and the cladding layers 120 as a mask to form the i-type non-crystalline thin films 11 to 1m1 and the p-type non-crystalline thin films 31 to 3m (refer to Process (g-2) of FIG. 15). Then, the resists 120′ are removed.

If the i-type non-crystalline thin films 11 to 1m and the p-type non-crystalline thin films 31 to 3m are formed, the p-type non-crystalline thin films 31 to 3m side of the p-type non-crystalline thin films 31 to 3m/i-type non-crystalline thin films 11 to 1m/n-type monocrystalline silicon substrate 1/non-crystalline thin film 2 is cleaned with hydrofluoric acid or the like, and the p-type non-crystalline thin films 31 to 3m/i-type non-crystalline thin films 11 to 1m/n-type monocrystalline silicon substrate 1/non-crystalline thin film 2 is put into the plasma CVD apparatus.

An SiH₄ gas and a PH₃ gas are caused to flow into the reaction chamber. The pressure of the reaction chamber is set to, for example, 30 Pa to 600 Pa, and the temperature of the substrate is set to, for example, 100° C. to 300° C. The RF power supply applies the RF power to the parallel plate electrodes through the matcher. Accordingly, the n-type non-crystalline thin films 41 to 4m-1 configured of n-type a-Si are accumulated on the n-type monocrystalline silicon substrate 1 in contact with the n-type monocrystalline silicon substrate 1, and n-type non-crystalline thin films 130 that are configured of n-type a-Si are accumulated on the cladding layers 120 (refer to Process (h-2) of FIG. 16).

If the n-type non-crystalline thin films 41 to 4m-1 are accumulated on the n-type monocrystalline silicon substrate 1, the non-crystalline thin film 2/n-type monocrystalline silicon substrate 1/i-type non-crystalline thin films 11 to 1m/p-type non-crystalline thin films 31 to 3m1 and n-type non-crystalline thin films 41 to 4m-1/cladding layers 120/n-type non-crystalline thin films 130 are withdrawn from the plasma CVD apparatus.

The cladding layers 120 are removed by etching using, for example, hydrofluoric acid. Accordingly, the n-type non-crystalline thin films 130 are removed by being lift-off (refer to Process (i-2) of FIG. 16).

Then, Process (j) illustrated in FIG. 4 is performed. The electrodes 51 to 5m are respectively formed on the p-type non-crystalline thin films 31 to 3m, and the electrodes 61 to 6m-1 are respectively formed on the n-type non-crystalline thin films 41 to 4m-1. Accordingly, the photoelectric conversion element 300 is completed.

The power generation mechanism of the photoelectric conversion element 300 is the same as the power generation mechanism of the above photoelectric conversion element 100. Thus, the photoelectric conversion element 300 is also a back contact type photoelectric conversion element. Also in the photoelectric conversion element 300, the non-crystalline thin film 2 is formed in contact with the surface on the light incident side of the n-type monocrystalline silicon substrate 1.

Therefore, an absorption layer (non-crystalline thin film 202) absorbs at least a part of light having a wavelength corresponding to energy greater than or equal to the bond energy of 3.4 eV between hydrogen and silicon that is an atom other than a hydrogen atom constituting the non-crystalline thin film 202, and photodegradation of the photoelectric conversion element 300 can be reduced.

While a texture structure is described above as being formed on the surface on the light incident side of the n-type monocrystalline silicon substrate 1, in the third embodiment, the texture structure is not limited thereto and may be also formed on the surface of the n-type monocrystalline silicon substrate 1 on the opposite side to the light incident side.

Other descriptions in the third embodiment are the same as the descriptions in the first embodiment.

### Fourth Embodiment

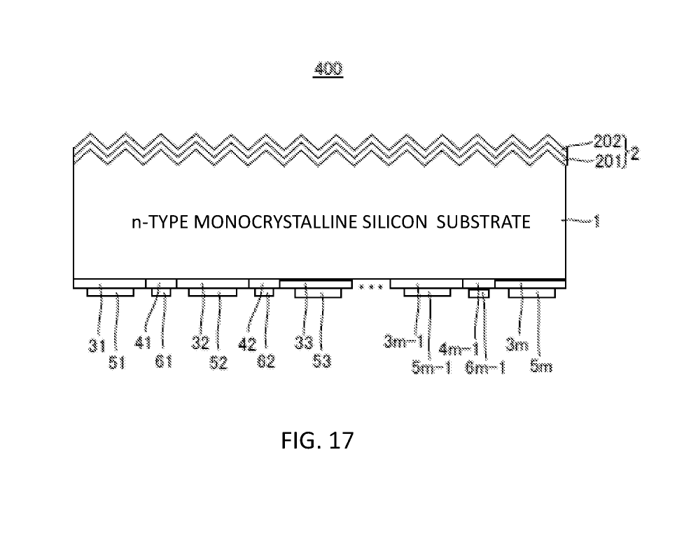

FIG. 17 is a sectional view illustrating a configuration of a photoelectric conversion element according to a fourth embodiment. With reference to FIG. 17, a photoelectric conversion element 400 according to the fourth embodiment is the same as the photoelectric conversion element 100 except that the i-type non-crystalline thin films 11 to 1m and 21 to 2m-1 of the photoelectric conversion element 100 illustrated in FIG. 1 are removed.

In the photoelectric conversion element 400, the p-type non-crystalline thin films 31 to 3m and the n-type non-crystalline thin films 41 to 4m-1 are arranged in contact with the n-type monocrystalline silicon substrate 1.

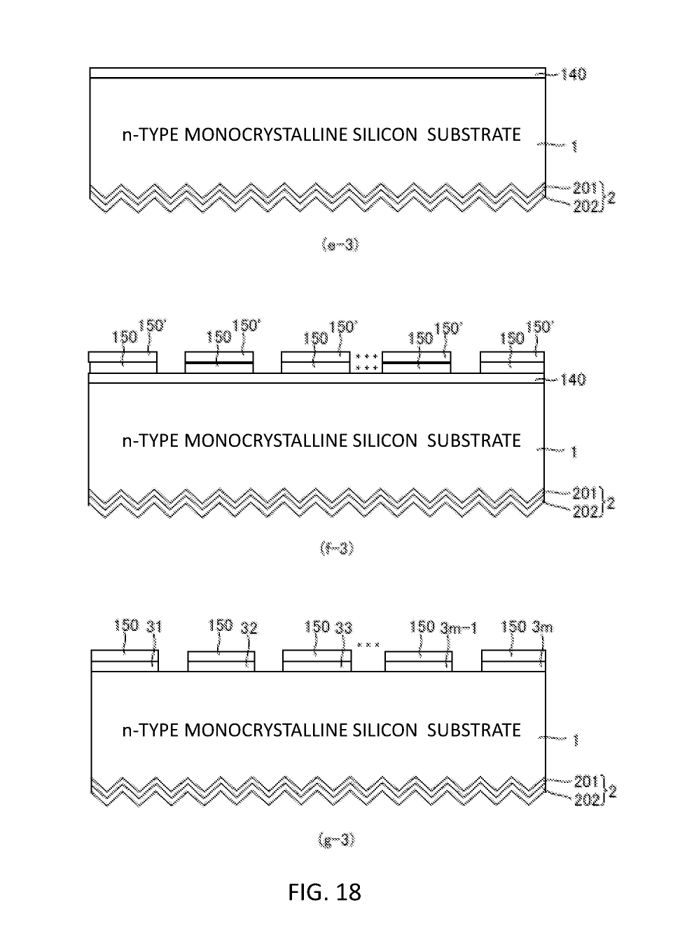

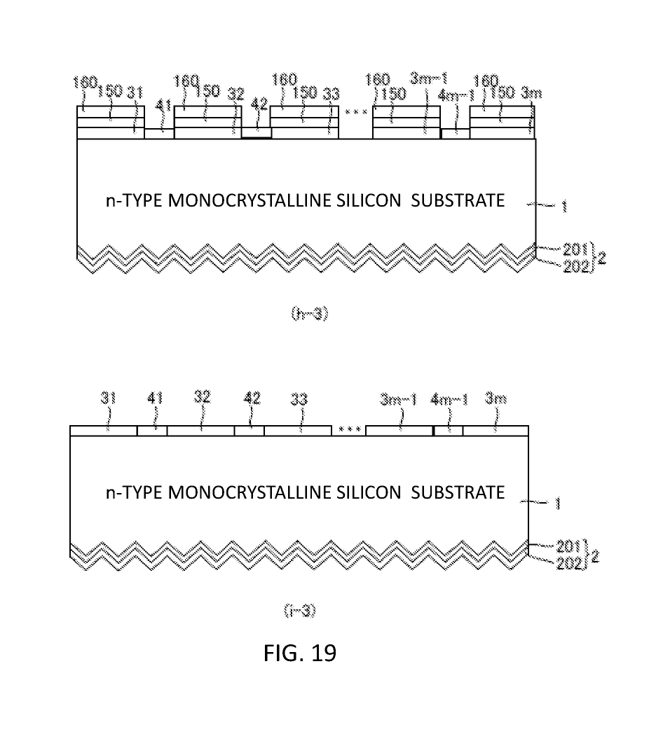

FIG. 18 and FIG. 19 are partial process charts for manufacturing the photoelectric conversion element 400 illustrated in FIG. 17.

The photoelectric conversion element 400 is manufactured in accordance with a process in which Process (e) to Process (i) of Process (a) to Process (k) illustrated in FIG. 2 to FIG. 4 are respectively replaced by Process (e-3) to Process (i-3) illustrated in FIG. 18 and FIG. 19.

If manufacturing of the photoelectric conversion element 400 is started, above Process (a) to Process (d) are performed in order.

After Process (d), the non-crystalline thin film 2/n-type monocrystalline silicon substrate 1 is withdrawn from the plasma CVD apparatus, and the non-crystalline thin film 2/n-type monocrystalline silicon substrate 1 is put into the plasma CVD apparatus in such a manner that a thin film can be accumulated on the rear surface (surface on the opposite side to the surface on which the non-crystalline thin film 2 is formed) of the n-type monocrystalline silicon substrate 1.

Then, an SiH₄ gas and a B₂H₆ gas are caused to flow into the reaction chamber. The pressure of the reaction chamber is set to, for example, 30 Pa to 600 Pa, and the RF power supply applies the RF power to the parallel plate electrodes through the matcher. Accordingly, a p-type non-crystalline thin film 140 that is configured of p-type a-Si is accumulated on the n-type monocrystalline silicon substrate 1 (refer to Process (e-3) of FIG. 18).

Then, an SiH₄ gas and an NH₃ gas are caused to flow into the reaction chamber. The pressure of the reaction chamber is set to, for example, 30 Pa to 600 Pa, and the RF power supply applies the RF power to the parallel plate electrodes through the matcher. Accordingly, a cladding layer that is configured of a-SiN is formed on the p-type non-crystalline thin film 140. The cladding layer may be configured of silicon oxide. A resist pattern is formed on the cladding layer by photolithography, and then, the cladding layer in opening portions of the resist is etched by using hydrofluoric acid or the like to form cladding layers 150 that are arranged at desired intervals on the p-type non-crystalline thin film 140 (refer to Process (f-3) of FIG. 18).

The p-type non-crystalline thin film 140 is etched by dry etching or wet etching with resists 150′ and the cladding layers 150 as a mask to form the p-type non-crystalline thin films 31 to 3m (refer to Process (g-3) of FIG. 18). Then, the resists 150′ are removed.

If the p-type non-crystalline thin films 31 to 3m are formed, the p-type non-crystalline thin films 31 to 3m side of the p-type non-crystalline thin films 31 to 3m/n-type monocrystalline silicon substrate 1/non-crystalline thin film 2 is cleaned with hydrofluoric acid or the like, and the p-type non-crystalline thin films 31 to 3m/n-type monocrystalline silicon substrate 1/non-crystalline thin film 2 is put into the plasma CVD apparatus.

An SiH₄ gas and a PH₃ gas are caused to flow into the reaction chamber. The pressure of the reaction chamber is set to, for example, 30 Pa to 600 Pa, and the temperature of the substrate is set to, for example, 100° C. to 300° C. The RF power supply applies the RF power to the parallel plate electrodes through the matcher. Accordingly, the n-type non-crystalline thin films 41 to 4m-1 configured of n-type a-Si are accumulated on the n-type monocrystalline silicon substrate 1 in contact with the n-type monocrystalline silicon substrate 1, and n-type non-crystalline thin films 160 that are configured of n-type a-Si are accumulated on the cladding layers 150 (refer to Process (h-3) of FIG. 19).

If the n-type non-crystalline thin films 41 to 4m-1 are accumulated on the n-type monocrystalline silicon substrate 1, the non-crystalline thin film 2/n-type monocrystalline silicon substrate 1/p-type non-crystalline thin films 31 to 3m1 and n-type non-crystalline thin films 41 to 4m-1/cladding layers 150/n-type non-crystalline thin films 160 are withdrawn from the plasma CVD apparatus.

The cladding layers 150 are removed by etching using, for example, hydrofluoric acid. Accordingly, the n-type non-crystalline thin films 160 are removed by being lift-off (refer to Process (i-3) of FIG. 19).

Then, Process (j) illustrated in FIG. 4 is performed. The electrodes 51 to 5m are respectively formed on the p-type non-crystalline thin films 31 to 3m, and the electrodes 61 to 6m-1 are respectively formed on the n-type non-crystalline thin films 41 to 4m-1. Accordingly, the photoelectric conversion element 400 is completed.

The power generation mechanism of the photoelectric conversion element 400 is the same as the power generation mechanism of the above photoelectric conversion element 100. Thus, the photoelectric conversion element 400 is also a back contact type photoelectric conversion element.

Also in the photoelectric conversion element 400, the non-crystalline thin film 2 is formed in contact with the surface on the light incident side of the n-type monocrystalline silicon substrate 1.

Therefore, an absorption layer (non-crystalline thin film 202) absorbs at least a part of light having a wavelength corresponding to energy greater than or equal to the bond energy of 3.4 eV between hydrogen and silicon that is an atom other than a hydrogen atom constituting the non-crystalline thin film 202, and photodegradation of the photoelectric conversion element 400 can be reduced.

While a texture structure is described above as being formed on the surface on the light incident side of the n-type monocrystalline silicon substrate 1, in the fourth embodiment, the texture structure is not limited thereto and may be also formed on the surface of the n-type monocrystalline silicon substrate 1 on the opposite side to the light incident side.

Other descriptions in the fourth embodiment are the same as the descriptions in the first embodiment.

### Fifth Embodiment

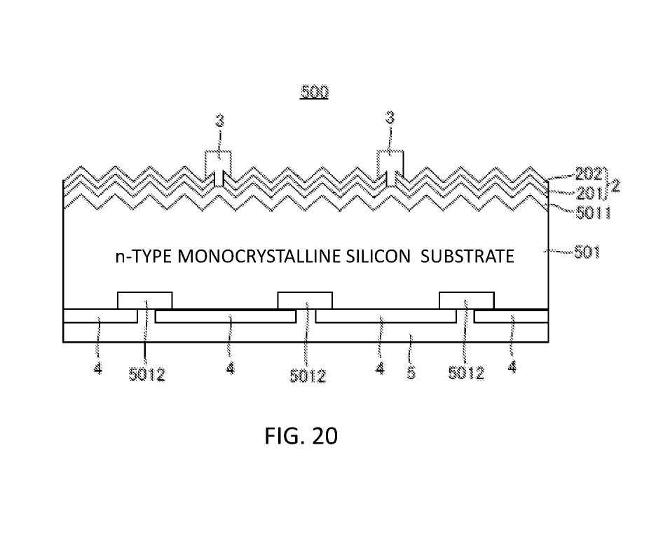

FIG. 20 is a sectional view illustrating a configuration of a photoelectric conversion element according to a fifth embodiment. With reference to FIG. 20, a photoelectric conversion element 500 according to the fifth embodiment includes an n-type monocrystalline silicon substrate 501, the non-crystalline thin film 2, electrodes 3 and 5, and an insulating layer 4.

The n-type monocrystalline silicon substrate 501 includes a p-type diffusion layer 5011 and n-type diffusion layers 5012. The p-type diffusion layer 5011 is arranged in contact with the surface on the light incident side of the n-type monocrystalline silicon substrate 501. The p-type diffusion layer 5011 includes, for example, boron (B) as a p-type impurity, and the maximum concentration of boron (B) is, for example, 1×10¹⁸ cm⁻³ to 1×10²⁰ cm⁻³. The p-type diffusion layer 5011 has a thickness of, for example, 10 nm to 1000 nm.

The n-type diffusion layers 5012 are arranged at desired intervals in the in-plane direction of the n-type monocrystalline silicon substrate 501 in contact with the rear surface of the n-type monocrystalline silicon substrate 501 on the opposite side to the surface on the light incident side. The n-type diffusion layers 5012 include, for example, phosphorus (P) as an n-type impurity, and the maximum concentration of phosphorus (P) is, for example, 1×10¹⁸ cm⁻³ to 1×10²⁰ cm⁻³. The n-type diffusion layers 5012 have a thickness of, for example, 10 nm to 1000 nm.

Other descriptions of the n-type monocrystalline silicon substrate 501 are the same as the descriptions of the n-type monocrystalline silicon substrate 1.

The non-crystalline thin film 2 is arranged in contact with the surface on the light incident side of the n-type monocrystalline silicon substrate 501. A detailed description of the non-crystalline thin film 2 is the same as described in the first embodiment.

The electrodes 3 are arranged on the non-crystalline thin film 2 and also pass through the non-crystalline thin film 2 to be in contact with the p-type diffusion layer 5011 of the n-type monocrystalline silicon substrate 501. The electrodes 3 are configured of a conductive material such as Ag or aluminum (Al).

The insulating layer 4 is arranged in contact with the rear surface of the n-type monocrystalline silicon substrate 501. The insulating layer 4 is configured of silicon oxide, silicon nitride, silicon oxynitride, aluminum oxide, and the like. The insulating layer 4 has a thickness of 50 nm to 100 nm.

The electrode 5 is arranged to cover the insulating layer 4 and also passes through the insulating layer 4 to be in contact with the n-type diffusion layers 5012 of the n-type monocrystalline silicon substrate 501. The electrode 5 is configured of a conductive material such as Ag or Al.

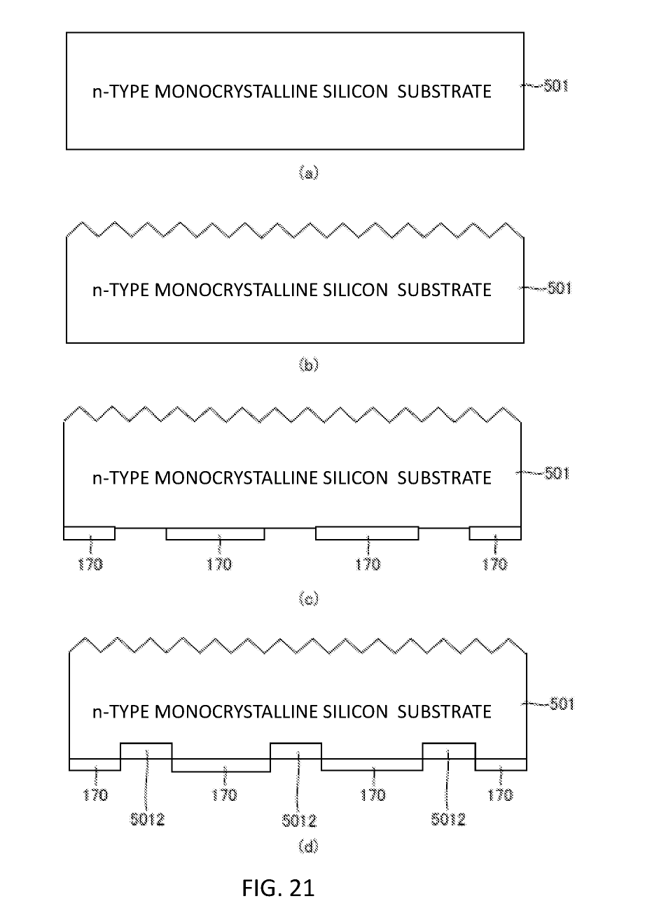

FIG. 21 to FIG. 24 are respectively first to fourth process charts illustrating a manufacturing method for the photoelectric conversion element 500 illustrated in FIG. 20.

With reference to FIG. 21, if manufacturing of the photoelectric conversion element 500 is started, the same processes as Process (a) and Process (b) illustrated in FIG. 2 are performed in order. Accordingly, the n-type monocrystalline silicon substrate 501 in which a texture structure is formed on the surface on the light incident side thereof is formed (refer to Process (a) and Process (b) of FIG. 21).

After Process (b), a resist is applied to the rear surface of the n-type monocrystalline silicon substrate 501, and the applied resist is patterned by photolithography and etching to form a resist pattern 170 (refer to Process (c) of FIG. 21).

The n-type monocrystalline silicon substrate 501 is doped with an n-type impurity such as P and arsenic (As) by using, for example, ion implantation with the resist pattern 170 as a mask. Accordingly, the n-type diffusion layers 5012 are formed on the rear surface side of the n-type monocrystalline silicon substrate 501 (refer to Process (d) of FIG. 21). After doping, heat treating may be performed in order to electrically activate the n-type impurity. Gas-phase diffusion, solid-phase diffusion, plasma doping, ion doping, and the like may be used instead of ion implantation.

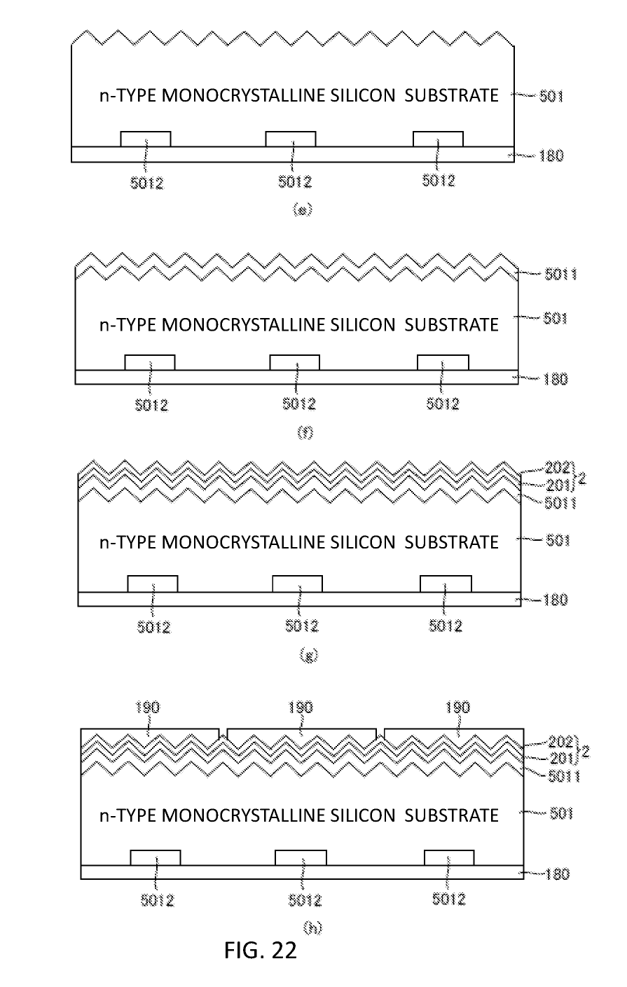

Then, the resist pattern 170 is removed. An insulating layer 180 that is configured of silicon nitride is formed on the entire rear surface of the n-type monocrystalline silicon substrate 501 by plasma CVD (refer to Process (e) of FIG. 22). The insulating layer 180 may be formed by atomic layer deposition (ALD), thermal CVD, and the like.

Next, the n-type monocrystalline silicon substrate 501 is doped with a p-type impurity such as B, gallium (Ga), and indium (In) from the light incident side by using, for example, ion implantation. Accordingly, the p-type diffusion layer 5011 is formed on the light incident side of the n-type monocrystalline silicon substrate 501 (refer to Process (f) of FIG. 22). After doping, heat treating may be performed in order to electrically activate the p-type impurity. The p-type diffusion layer 5011 may be formed by using gas-phase diffusion, solid-phase diffusion, plasma doping, ion doping, and the like instead of ion implantation.

The same process as Process (d) illustrated in FIG. 2 is performed to form the non-crystalline thin film 2 in contact with the surface on the light incident side of the n-type monocrystalline silicon substrate 501 using the above method (refer to Process (g) of FIG. 22).

Then, a resist is applied to the entire surface of the non-crystalline thin film 2, and the applied resist is patterned by photolithography and etching to form a resist pattern 190 (refer to Process (h) of FIG. 22).

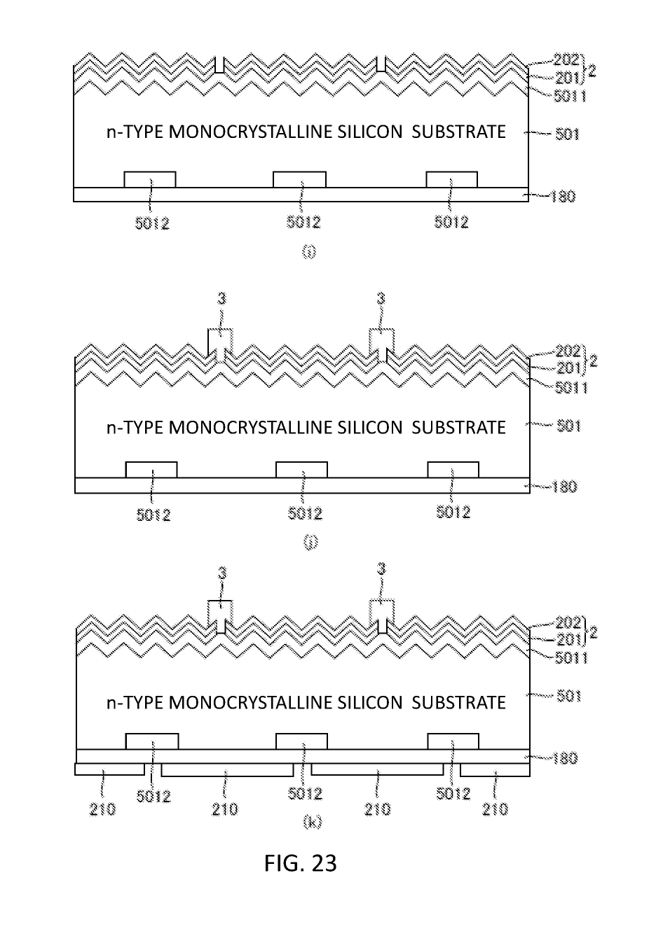

A part of the non-crystalline thin film 2 is etched by using a liquid mixture of hydrofluoric acid and nitric acid with the resist pattern 190 as a mask, and then, the resist pattern 190 is removed. Accordingly, a part of the p-type diffusion layer 5011 is exposed (refer to Process (i) of FIG. 23).

Then, a metal film made of Ag, Al, or the like is formed on the entire surface of the non-crystalline thin film 2 by using vapour deposition, sputtering, or the like, and the formed metal film is patterned. Accordingly, the electrodes 3 are formed (refer to Process (j) of FIG. 23). The electrodes 3 may be formed by patterning a metal paste using printing or the like.

A resist is applied to the entire surface of the insulating layer 180, and the applied resist is patterned by photolithography and etching to form a resist pattern 210 (refer to Process (k) of FIG. 23).

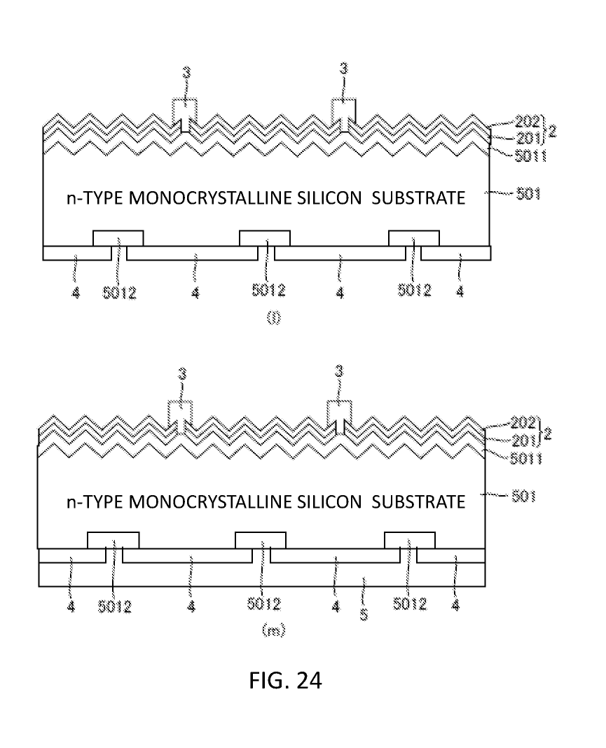

Then, a part of the insulating layer 180 is etched by using hydrofluoric acid or the like with the resist pattern 210 as a mask, and the resist pattern 210 is removed. Accordingly, a part of the n-type diffusion layers 5012 of the n-type monocrystalline silicon substrate 501 is exposed, and the insulating layer 4 is formed (refer to Process (1) of FIG. 24).

Next, a metal film made of Ag, Al, or the like is formed to cover the insulating layer 4 by using vapour deposition, sputtering, or the like. Accordingly, the electrode 5 is formed, and the photoelectric conversion element 500 is completed (refer to Process (m) of FIG. 24).

In the photoelectric conversion element 500, if the photoelectric conversion element 500 is irradiated with sunlight from the non-crystalline thin film 2 side thereof, the non-crystalline thin film 202 of the non-crystalline thin film 2 absorbs at least a part of light having a wavelength less than or equal to 365 nm and guides the remaining light into the n-type monocrystalline silicon substrate 501 through the non-crystalline thin film 201. Then, electrons and electron holes are optically excited in the n-type monocrystalline silicon substrate 501. Since the non-crystalline thin film 202 absorbs at least a part of light having a wavelength less than or equal to 365 nm, the Si—H bonds in the a-Si constituting the non-crystalline thin film 201 are unlikely to be cleaved, and an increase of the defect density of the non-crystalline thin film 201 is suppressed.

The optically excited electrons and electron holes are separated by an internal electric field caused by the p-type diffusion layer 5011/(bulk region of n-type monocrystalline silicon substrate 501). The electron holes reach the electrodes 3 through the p-type diffusion layer 5011, and the electrons are diffused toward the n-type diffusion layers 5012 and reach the electrode 5 through the n-type diffusion layers 5012.

The electrons that reach the electrode 5 reach the electrodes 3 through loads connected between the electrodes 3 and the electrode 5 and recombine with the electron holes.

In the photoelectric conversion element 500, the surface on the light incident side of the n-type monocrystalline silicon substrate 501 is covered by the non-crystalline thin film 2, and the rear surface of the n-type monocrystalline silicon substrate 501 is covered by the insulating layer 4.

Therefore, an absorption layer (non-crystalline thin film 202) absorbs ultraviolet light, and photodegradation of the photoelectric conversion element 500 can be reduced. In addition, the rear surface of the n-type monocrystalline silicon substrate 501 can be passivated by the insulating layer 4.

The photoelectric conversion element 500 may include an n-type diffusion layer instead of the p-type diffusion layer 5011 and include p-type diffusion layers instead of the n-type diffusion layers 5012.

While a texture structure is described as being formed on the surface on the light incident side of the n-type monocrystalline silicon substrate 501, in the fifth embodiment, the texture structure is not limited thereto and may be also formed on the surface of the n-type monocrystalline silicon substrate 501 on the opposite side to the light incident side.

Other descriptions in the fifth embodiment are the same as the descriptions in the first embodiment.

### Sixth Embodiment

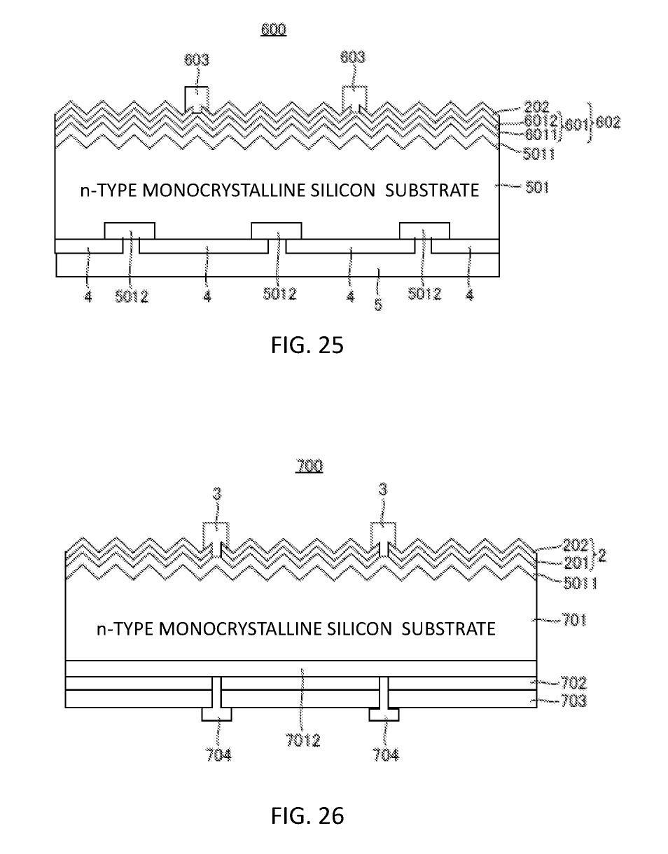

FIG. 25 is a sectional view illustrating a configuration of a photoelectric conversion element according to a sixth embodiment. With reference to FIG. 25, a photoelectric conversion element 600 according to the sixth embodiment is the same as the photoelectric conversion element 500 except that the non-crystalline thin film 2 of the photoelectric conversion element 500 illustrated in FIG. 20 is replaced by an non-crystalline thin film 602 and that the electrodes 3 are replaced by electrodes 603.

The non-crystalline thin film 602 is the same as the non-crystalline thin film 2 except that the non-crystalline thin film 201 of the non-crystalline thin film 2 is replaced by an non-crystalline thin film 601.

The non-crystalline thin film 601 is configured of non-crystalline thin films 6011 and 6012. The non-crystalline thin film 6011 includes at least an non-crystalline phase and is configured of, for example, a-Si. The non-crystalline thin film 6011 is preferably configured of i-type a-Si and may include a p-type impurity that has a concentration lower than the concentration of a p-type impurity included in the non-crystalline thin film 6012. The non-crystalline thin film 6011 has a thickness of, for example, 1 nm to 20 nm. The non-crystalline thin film 6011 is arranged on the p-type diffusion layer 5011 in contact with the p-type diffusion layer 5011 of the n-type monocrystalline silicon substrate 501 to passivate the n-type monocrystalline silicon substrate 501.

The non-crystalline thin film 6012 includes at least an non-crystalline phase and is configured of, for example, p-type a-Si. The non-crystalline thin film 6012 has a thickness of, for example, 1 nm to 30 nm. The non-crystalline thin film 6012 is arranged on the non-crystalline thin film 6011 in contact with the non-crystalline thin film 6011.

In the photoelectric conversion element 600, the non-crystalline thin film 202 is arranged on the non-crystalline thin film 6012 in contact with the non-crystalline thin film 6012.

The electrodes 603 are configured of, for example, Ag or Al. The electrodes 603 are arranged on the non-crystalline thin film 202 and pass through the non-crystalline thin film 202 to be in contact with the non-crystalline thin film 6012.

The photoelectric conversion element 600 is manufactured in accordance with a process chart in which Process (g) of Process (a) to Process (m) illustrated in FIG. 21 to FIG. 24 is replaced by a process of stacking the non-crystalline thin film 6011, the non-crystalline thin film 6012, and the non-crystalline thin film 202 in order on the surface on the light incident side of the n-type monocrystalline silicon substrate 501 using plasma CVD. In this case, in Process (i), a part of the non-crystalline thin film 202 is etched, and the non-crystalline thin film 6012 is exposed. The electrodes 603 may be formed by printing with a metal paste made of Ag, Al, and the like.

In the photoelectric conversion element 600, if the photoelectric conversion element 600 is irradiated with sunlight from the non-crystalline thin film 602 side thereof, the non-crystalline thin film 202 of the non-crystalline thin film 602 absorbs at least a part of light having a wavelength less than or equal to 365 nm and guides the remaining light into the n-type monocrystalline silicon substrate 501 through the non-crystalline thin films 6012 and 6011. Then, electrons and electron holes are optically excited in the n-type monocrystalline silicon substrate 501. Since the non-crystalline thin film 202 absorbs at least a part of light having a wavelength less than or equal to 365 nm, the Si—H bonds in the a-Si constituting the non-crystalline thin films 6011 and 6012 are unlikely to be cleaved, and an increase of the defect density of the non-crystalline thin films 6011 and 6012 is suppressed.

The optically excited electrons and electron holes are separated by an internal electric field caused by (non-crystalline thin film 6012 and p-type diffusion layer 5011)/(bulk region of n-type monocrystalline silicon substrate 501). The electron holes reach the electrodes 603 through the p-type diffusion layer 5011 and the non-crystalline thin films 6011 and 6012, and the electrons are diffused toward the n-type diffusion layers 5012 and reach the electrode 5 through the n-type diffusion layers 5012.

The electrons that reach the electrode 5 reach the electrodes 3 through loads connected between the electrodes 3 and the electrode 5 and recombine with the electron holes.

In the photoelectric conversion element 600, the surface on the light incident side of the n-type monocrystalline silicon substrate 501 is covered by the non-crystalline thin film 602, and the rear surface of the n-type monocrystalline silicon substrate 501 is covered by the insulating layer 4. The non-crystalline thin film 602 includes the non-crystalline thin film 202 that absorbs at least a part of light having a wavelength less than or equal to 365 nm.

Therefore, an absorption layer (non-crystalline thin film 202) absorbs ultraviolet light, and photodegradation of the photoelectric conversion element 600 can be reduced. In addition, the rear surface of the n-type monocrystalline silicon substrate 501 can be passivated by the insulating layer 4.

In the photoelectric conversion element 600, there exists no region in which metal (electrodes 603) that significantly decreases the lifetime of minority carriers is in contact with the n-type monocrystalline silicon substrate 501. As a result, significantly favorable passivation characteristics are obtained for the n-type monocrystalline silicon substrate 501, and a high open-circuit voltage (Voc) and a high fill factor (FF) can be obtained. Therefore, characteristics of the photoelectric conversion element 600 can be improved.

In the photoelectric conversion element 600, any one of the non-crystalline thin films 6011 and 6012 may not be present. The electrodes 603 are in contact with the non-crystalline thin film 6012 in a case where the non-crystalline thin film 6011 is not present. The electrodes 603 are in contact with the non-crystalline thin film 6011 in a case where the non-crystalline thin film 6012 is not present. Therefore, also in a case where any one of the non-crystalline thin films 6011 and 6012 is not present, there exists no region in which metal (electrodes 603) is in contact with the n-type monocrystalline silicon substrate 501.

In the photoelectric conversion element 600, the p-type diffusion layer 5011 may be replaced by an n-type diffusion layer, the n-type diffusion layers 5012 may be replaced by p-type diffusion layers, and the non-crystalline thin film 6012 may be configured of n-type a-Si. In this case, the non-crystalline thin film 6011 is configured of i-type a-Si or n-type a-Si.

While a texture structure is described as being formed on the surface on the light incident side of the n-type monocrystalline silicon substrate 501, in the sixth embodiment, the texture structure is not limited thereto and may be also formed on the surface of the n-type monocrystalline silicon substrate 501 on the opposite side to the light incident side.

Other descriptions in the sixth embodiment are the same as the descriptions in the first embodiment.

### Seventh Embodiment

FIG. 26 is a sectional view illustrating a configuration of a photoelectric conversion element according to a seventh embodiment. With reference to FIG. 26, a photoelectric conversion element 700 according to the seventh embodiment is the same as the photoelectric conversion element 500 except that the n-type monocrystalline silicon substrate 501 of the photoelectric conversion element 500 illustrated in FIG. 20 is replaced by an n-type monocrystalline silicon substrate 701, the insulating film 4 is replaced by non-crystalline thin films 702 and 703, and the electrode 5 is replaced by electrodes 704.

The n-type monocrystalline silicon substrate 701 is the same as the n-type monocrystalline silicon substrate 501 except that the n-type diffusion layers 5012 of the n-type monocrystalline silicon substrate 501 are replaced by an n-type diffusion layer 7012.

The n-type diffusion layer 7012 is arranged in the n-type monocrystalline silicon substrate 701 in contact with the entire rear surface of the n-type monocrystalline silicon substrate 701 on the opposite side to the light incident side. The n-type diffusion layer 7012 has the same thickness as the n-type diffusion layers 5012 and includes an n-type impurity that has the same concentration as the n-type impurity of the n-type diffusion layers 5012. Other descriptions of the n-type monocrystalline silicon substrate 701 are the same as the descriptions of the n-type monocrystalline silicon substrate 1.

The non-crystalline thin film 702 includes at least an non-crystalline phase and is configured of, for example, i-type a-Si or n-type a-Si. The non-crystalline thin film 702 may be configured of stacked films in which n-type a-Si is formed on i-type a-Si. The thickness of the non-crystalline thin film 702 is, for example, 1 nm to 200 nm. The non-crystalline thin film 702 is arranged on the n-type monocrystalline silicon substrate 701 in contact with the rear surface of the n-type monocrystalline silicon substrate 701 on the opposite side to the light incident side.

The non-crystalline thin film 703 includes at least an non-crystalline phase and is configured of, for example, a-SiNₓ. The thickness of the non-crystalline thin film 703 is the same as the non-crystalline thin film 202. The composition ratio x is such that x>0 in a case where the photoelectric conversion element 700 is used as a single-sided light reception type photoelectric conversion element. Meanwhile, in a case where the photoelectric conversion element 700 is used as a double-sided light reception type photoelectric conversion element, the composition ratio x is preferably such that 0<x<0.85 and more preferably such that 0<x≦0.78. The non-crystalline thin film 703 is arranged on the non-crystalline thin film 702 in contact with the non-crystalline thin film 702.

The electrodes 704 are configured of, for example, Ag or Al. The electrodes 704 are arranged on the non-crystalline thin film 703 and pass through the non-crystalline thin films 702 and 703 to be in contact with the n-type diffusion layer 7012.

In the photoelectric conversion element 700, the surface on the light incident side of the n-type monocrystalline silicon substrate 701 is passivated by the non-crystalline thin film 201, and the rear surface of the n-type monocrystalline silicon substrate 701 is passivated by the non-crystalline thin film 702.

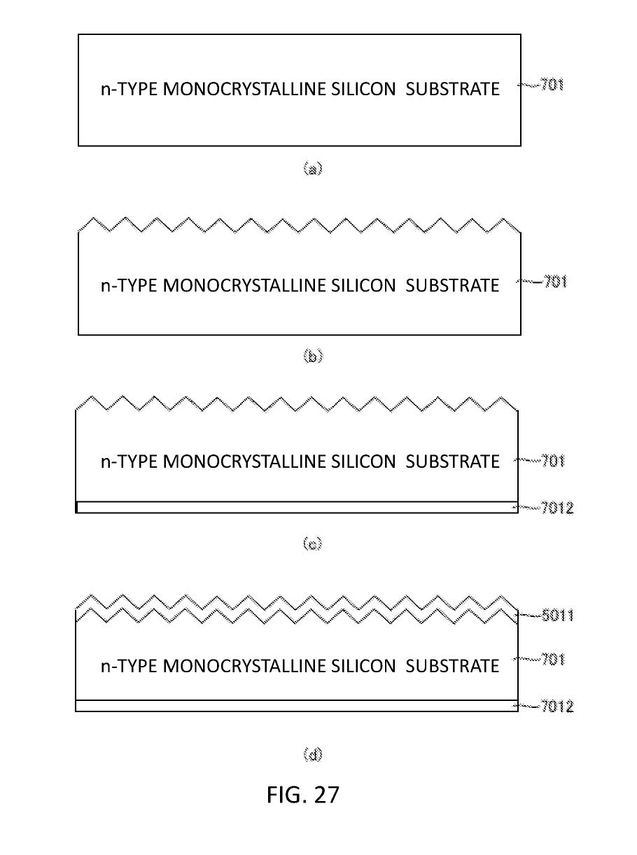

FIG. 27 to FIG. 30 are respectively first to fourth process charts illustrating a manufacturing method for the photoelectric conversion element 700 illustrated in FIG. 26.

With reference to FIG. 27, if manufacturing of the photoelectric conversion element 700 is started, the same processes as Process (a) and Process (b) illustrated in FIG. 2 are performed in order. Accordingly, the n-type monocrystalline silicon substrate 701 in which a texture structure is formed on the surface on the light incident side thereof is formed (refer to Process (a) and Process (b) of FIG. 27).

After Process (b), the entire rear surface of the n-type monocrystalline silicon substrate 701 is doped with an n-type impurity such as P and As by using, for example, ion implantation. Accordingly, the n-type diffusion layer 7012 is formed on the rear surface side of the n-type monocrystalline silicon substrate 701 (refer to Process (c) of FIG. 27). After doping, heat treating may be performed in order to electrically activate the n-type impurity. Gas-phase diffusion, solid-phase diffusion, plasma doping, ion doping, and the like may be used instead of ion implantation.

Next, the n-type monocrystalline silicon substrate 701 is doped with a p-type impurity such as B, Ga, and In from the light incident side by using, for example, ion implantation. Accordingly, the p-type diffusion layer 5011 is formed on the light incident side of the n-type monocrystalline silicon substrate 701 (refer to Process (d) of FIG. 27). After doping, heat treating may be performed in order to electrically activate the p-type impurity. The p-type diffusion layer 5011 may be formed by using gas-phase diffusion, solid-phase diffusion, plasma doping, ion doping, and the like instead of ion implantation.

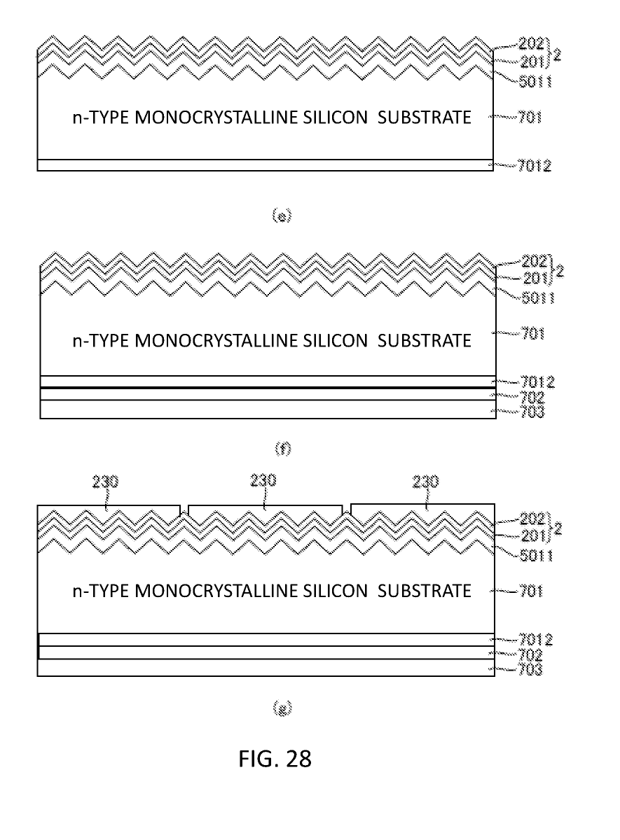

The same process as Process (d) illustrated in FIG. 2 is performed to form the non-crystalline thin film 2 in contact with the surface on the light incident side of the n-type monocrystalline silicon substrate 701 using the above method (refer to Process (e) of FIG. 28).

Then, the same process as Process (d) illustrated in FIG. 2 is performed to stack the non-crystalline thin films 702 and 703 in order on the rear surface of the n-type monocrystalline silicon substrate 701 (refer to Process (f) of FIG. 28).

A resist is applied to the entire surface of the non-crystalline thin film 2, and the applied resist is patterned by photolithography and etching to form a resist pattern 230 (refer to Process (g) of FIG. 28).

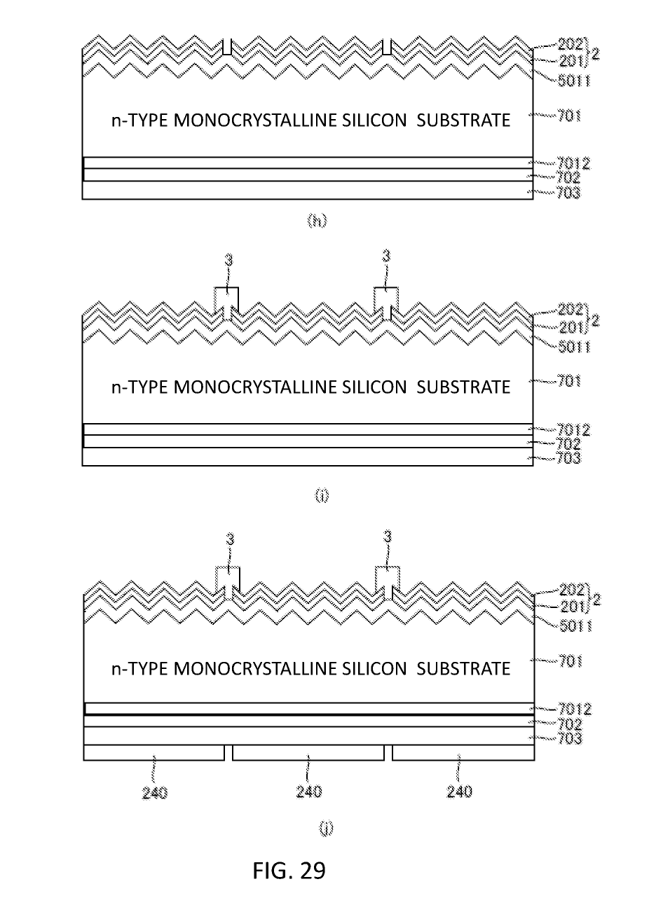

A part of the non-crystalline thin film 2 is etched with the resist pattern 230 as a mask, and the resist pattern 230 is removed. Accordingly, a part of the p-type diffusion layer 5011 is exposed (refer to Process (h) of FIG. 29).

Then, a metal film made of Ag, Al, or the like is formed on the entire surface of the non-crystalline thin film 2 by using vapour deposition, sputtering, or the like, and the formed metal film is patterned by using, for example, photolithography. Accordingly, the electrodes 3 are formed (refer to Process (i) of FIG. 29). The electrodes 3 may be formed by patterning a metal paste or the like using printing or the like.

A resist is applied to the entire surface of the non-crystalline thin film 703, and the applied resist is patterned by photolithography and etching to form a resist pattern 240 (refer to Process (j) of FIG. 29).

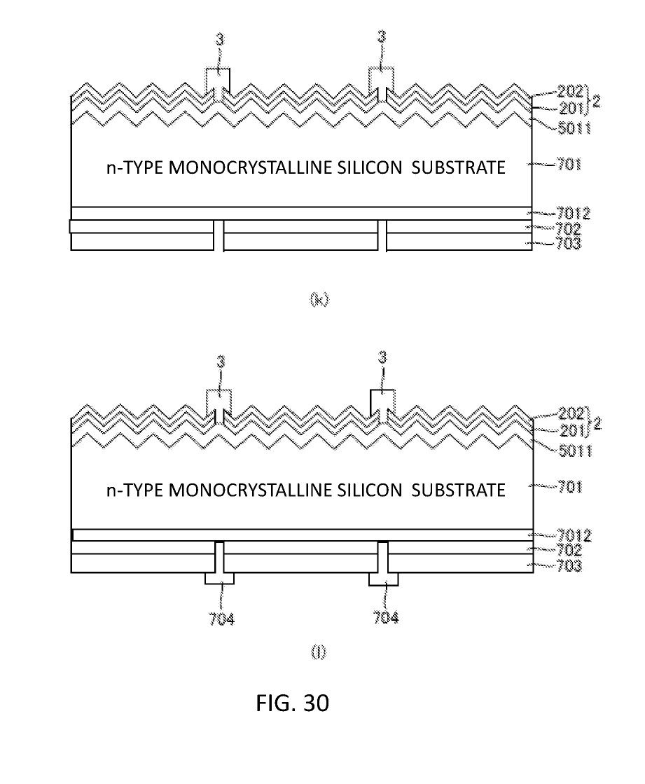

Then, a part of the non-crystalline thin films 702 and 703 is etched with the resist pattern 240 as a mask, and the resist pattern 240 is removed. Accordingly, a part of the n-type diffusion layer 7012 of the n-type monocrystalline silicon substrate 701 is exposed (refer to Process (k) of FIG. 30).

Next, a metal film made of Ag, Al, or the like is formed to cover the non-crystalline thin films 702 and 703 by using vapour deposition, sputtering, or the like, and the formed metal film is patterned to form the electrodes 704. Accordingly, the photoelectric conversion element 700 is completed (refer to Process (1) of FIG. 30). The electrodes 704 may be formed by patterning a metal paste or the like using printing or the like.

The power generation mechanism of the photoelectric conversion element 700 is the same as the power generation mechanism of the photoelectric conversion element 500. In the photoelectric conversion element 700, the surface on the light incident side of the n-type monocrystalline silicon substrate 701 is covered by the non-crystalline thin film 2, and the rear surface of the n-type monocrystalline silicon substrate 701 is covered by the non-crystalline thin films 702 and 703.

Therefore, an absorption layer (non-crystalline thin film 202) absorbs ultraviolet light in a case where light is incident from the non-crystalline thin film 2 side of the photoelectric conversion element 700, and photodegradation of the photoelectric conversion element 700 can be reduced. In addition, the rear surface of the n-type monocrystalline silicon substrate 701 can be passivated.

Meanwhile, an absorption layer (non-crystalline thin film 703) absorbs ultraviolet light in a case where light is incident from the non-crystalline thin films 702 and 703 side of the photoelectric conversion element 700, and photodegradation of the photoelectric conversion element 700 can be reduced. In addition, the surface of the n-type monocrystalline silicon substrate 701 on which a texture structure is formed can be passivated.

As such, even if light is incident from any surface of the n-type monocrystalline silicon substrate 701, either the non-crystalline thin film 202 or the non-crystalline thin film 703 absorbs ultraviolet light. Thus, photodegradation of the photoelectric conversion element 700 can be reduced.

In the photoelectric conversion element 700, the p-type diffusion layer 5011 may be replaced by an n-type diffusion layer, and the n-type diffusion layer 7012 may be replaced by a p-type diffusion layer. In this case, the non-crystalline thin film 201 is configured of i-type a-Si or n-type a-Si, and the non-crystalline thin film 702 is configured of i-type a-Si or p-type a-Si.

While a texture structure is described as being formed on the surface on the light incident side of the n-type monocrystalline silicon substrate 701, in the seventh embodiment, the texture structure is not limited thereto and may be also formed on the surface of the n-type monocrystalline silicon substrate 701 on the opposite side to the light incident side.

Other descriptions in the seventh embodiment are the same as the descriptions in the first embodiment.

### Eighth Embodiment

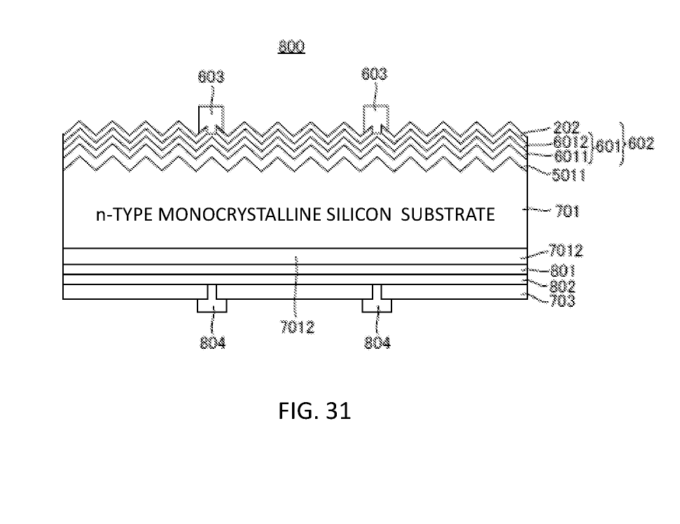

FIG. 31 is a sectional view illustrating a configuration of a photoelectric conversion element according to an eighth embodiment. With reference to FIG. 31, a photoelectric conversion element 800 according to the eighth embodiment is the same as the photoelectric conversion element 600 except that the n-type monocrystalline silicon substrate 501 of the photoelectric conversion element 600 illustrated in FIG. 25 is replaced by the n-type monocrystalline silicon substrate 701, the insulating film 4 is replaced by non-crystalline thin films 703, 801, and 802, and the electrode 5 is replaced by electrodes 804.

The n-type monocrystalline silicon substrate 701 is the same as described above.

The non-crystalline thin film 801 includes at least an non-crystalline phase and is configured of, for example, type a-Si or n-type a-Si. The non-crystalline thin film 801 is arranged on the rear surface of the n-type monocrystalline silicon substrate 701 in contact with the rear surface of the n-type monocrystalline silicon substrate 701. The thickness of the non-crystalline thin film 801 is, for example, 1 nm to 20 nm.

The non-crystalline thin film 802 includes at least an non-crystalline phase and is configured of, for example, n-type a-Si. The non-crystalline thin film 802 is arranged on the non-crystalline thin film 801 in contact with the non-crystalline thin film 801. The thickness of the non-crystalline thin film 802 is, for example, 1 nm to 30 nm.

In the photoelectric conversion element 800, the non-crystalline thin film 703 is arranged on the non-crystalline thin film 802 in contact with the non-crystalline thin film 802. Other descriptions of the non-crystalline thin film 703 are the same as described above.

The electrodes 804 are configured of, for example, Ag or Al. The electrodes 804 are arranged on the non-crystalline thin film 703 and pass through the non-crystalline thin film 703 to be in contact with the non-crystalline thin film 802.

The photoelectric conversion element 800 is manufactured in accordance with a process chart in which, in the process charts configured of Process (a) to Process (1) illustrated in FIG. 27 to FIG. 30, Process (e) is replaced by a process of stacking the non-crystalline thin films 6011, 6012, and 202 in order on the n-type monocrystalline silicon substrate 701 using plasma CVD, Process (h) is replaced by a process of etching a part of the non-crystalline thin film 202 to expose a part of the non-crystalline thin film 6012, Process (i) is replaced by a process of stacking the non-crystalline thin films 801, 802, and 703 in order on the rear surface of the n-type monocrystalline silicon substrate 701 using plasma CVD, and Process (k) is replaced by a process of etching a part of the non-crystalline thin film 703 to expose a part of the non-crystalline thin film 802.

The power generation mechanism of the photoelectric conversion element 800 is the same as the power generation mechanism of the photoelectric conversion element 700. Therefore, the photoelectric conversion element 800 is used as either a single-sided light reception type photoelectric conversion element or a double-sided light reception type photoelectric conversion element.

In the photoelectric conversion element 800, the surface on the light incident side of the n-type monocrystalline silicon substrate 701 is covered by the non-crystalline thin film 602, and the rear surface of the n-type monocrystalline silicon substrate 701 is covered by the non-crystalline thin films 801, 802, and 703.

Therefore, an absorption layer (non-crystalline thin film 202) absorbs ultraviolet light, and photodegradation of the photoelectric conversion element 800 can be reduced. In addition, the rear surface of the n-type monocrystalline silicon substrate 701 can be passivated.

Meanwhile, an absorption layer (non-crystalline thin film 703) absorbs ultraviolet light in a case where light is incident from the non-crystalline thin films 801, 802, and 703 side of the photoelectric conversion element 800, and photodegradation of the photoelectric conversion element 800 can be reduced. In addition, the surface of the n-type monocrystalline silicon substrate 701 on which a texture structure is formed can be passivated.

As such, even if light is incident from any surface of the n-type monocrystalline silicon substrate 701, either the non-crystalline thin film 202 or the non-crystalline thin film 703 absorbs ultraviolet light. Thus, photodegradation of the photoelectric conversion element 800 can be reduced.

Besides, the photoelectric conversion element 800 can accomplish the same effect as the photoelectric conversion element 600.

In the photoelectric conversion element 800, any one of the non-crystalline thin films 801 and 802 may not be present. The electrodes 804 are in contact with the non-crystalline thin film 802 in a case where the non-crystalline thin film 801 is not present. The electrodes 804 are in contact with the non-crystalline thin film 801 in a case where the non-crystalline thin film 802 is not present. Therefore, in a case where any one of the non-crystalline thin films 801 and 802 is not present, there exists no region in which the electrodes 804 are in contact with the n-type monocrystalline silicon substrate 701.

In the photoelectric conversion element 800, the p-type diffusion layer 5011 may be replaced by an n-type diffusion layer, and the n-type diffusion layer 7012 may be replaced by a p-type diffusion layer. In this case, the non-crystalline thin film 6011 is configured of i-type a-Si or n-type a-Si, the non-crystalline thin film 6012 is configured of n-type a-Si, the non-crystalline thin film 801 is configured of i-type a-Si or p-type a-Si, and the non-crystalline thin film 802 is configured of p-type a-Si.

Other descriptions of the photoelectric conversion element 800 are the same as the descriptions of the photoelectric conversion element 600.

While a texture structure is described above as being formed on the surface on the light incident side of the n-type monocrystalline silicon substrate 701, in the eighth embodiment, the texture structure is not limited thereto and may be also formed on the surface of the n-type monocrystalline silicon substrate 701 on the opposite side to the light incident side.

Other descriptions in the eighth embodiment are the same as the descriptions in the first embodiment.

### Ninth Embodiment

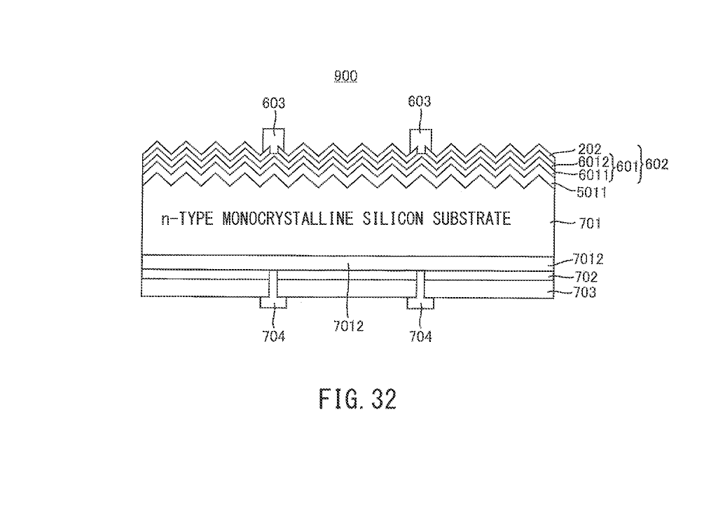

FIG. 32 is a sectional view illustrating a configuration of a photoelectric conversion element according to a ninth embodiment. With reference to FIG. 32, a photoelectric conversion element 900 according to the ninth embodiment is the same as the photoelectric conversion element 700 except that the non-crystalline thin film 2 of the photoelectric conversion element 700 illustrated in FIG. 26 is replaced by the non-crystalline thin film 602 and that the electrodes 3 are replaced by the electrodes 603.

The non-crystalline thin film 602 and the electrodes 603 are the same as described above.

The photoelectric conversion element 900 is manufactured in accordance with a process chart in which, in the process charts configured of Process (a) to Process (1) illustrated in FIG. 27 to FIG. 30, Process (e) is replaced by a process of stacking the non-crystalline thin films 6011, 6012, and 202 in order on the n-type monocrystalline silicon substrate 701 using plasma CVD and Process (h) is replaced by a process of etching a part of the non-crystalline thin film 202 to expose a part of the non-crystalline thin film 6012.

The power generation mechanism of the photoelectric conversion element 900 is the same as the power generation mechanism of the photoelectric conversion element 700. Therefore, the photoelectric conversion element 900 is used as either a single-sided light reception type photoelectric conversion element or a double-sided light reception type photoelectric conversion element.

In the photoelectric conversion element 900, the surface on the light incident side of the n-type monocrystalline silicon substrate 701 is covered by the non-crystalline thin film 602, and the rear surface of the n-type monocrystalline silicon substrate 701 is covered by the non-crystalline thin films 702 and 703.

Therefore, an absorption layer (non-crystalline thin film 202) absorbs ultraviolet light, and photodegradation of the photoelectric conversion element 900 can be reduced. In addition, the rear surface of the n-type monocrystalline silicon substrate 701 can be passivated.

Meanwhile, an absorption layer (non-crystalline thin film 703) absorbs ultraviolet light in a case where light is incident from the non-crystalline thin films 702 and 703 side of the photoelectric conversion element 900, and photodegradation of the photoelectric conversion element 900 can be reduced. In addition, the surface of the n-type monocrystalline silicon substrate 701 on which a texture structure is formed can be passivated.

As such, even if light is incident from any surface of the n-type monocrystalline silicon substrate 701, either the non-crystalline thin film 202 or the non-crystalline thin film 703 absorbs ultraviolet light. Thus, photodegradation of the photoelectric conversion element 900 can be reduced.

Besides, the photoelectric conversion element 900 can accomplish the same effect as the photoelectric conversion element 600.

In the photoelectric conversion element 900, the p-type diffusion layer 5011 may be replaced by an n-type diffusion layer, and the n-type diffusion layer 7012 may be replaced by a p-type diffusion layer. In this case, the non-crystalline thin film 6011 is configured of i-type a-Si or n-type a-Si, the non-crystalline thin film 6012 is configured of n-type a-Si, and the non-crystalline thin film 702 is configured of i-type a-Si or n-type a-Si.

Other descriptions of the photoelectric conversion element 900 are the same as the descriptions of the photoelectric conversion element 600.

While a texture structure is described above as being formed on the surface on the light incident side of the n-type monocrystalline silicon substrate 701, in the ninth embodiment, the texture structure is not limited thereto and may be also formed on the surface of the n-type monocrystalline silicon substrate 701 on the opposite side to the light incident side.

Other descriptions in the ninth embodiment are the same as the descriptions in the first embodiment.

### Tenth Embodiment

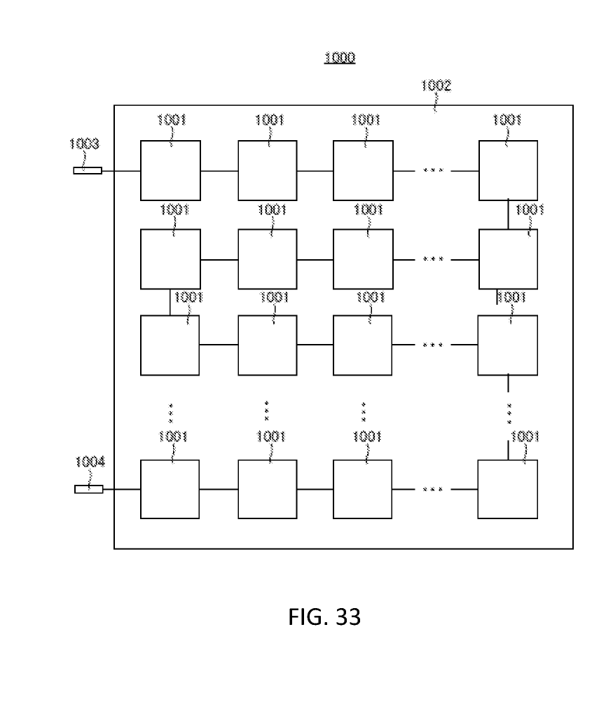

FIG. 33 is a schematic diagram illustrating a configuration of a photoelectric conversion module that includes the photoelectric conversion element according to the above embodiments. With reference to FIG. 33, a photoelectric conversion module 1000 includes a plurality of photoelectric conversion elements 1001, a cover 1002, and output terminals 1003 and 1004.

The plurality of photoelectric conversion elements 1001 is arranged in an array form and is connected in series. The plurality of photoelectric conversion elements 1001 may be connected in parallel instead of being connected in series or may be connected by combining serial connection and parallel connection.

Each of the plurality of photoelectric conversion elements 1001 is configured of any of the photoelectric conversion elements 100, 200, 300, 400, 500, 600, 700, 800, and 900.

The cover 1002 is configured of a weatherproof cover and covers the plurality of photoelectric conversion elements 1001.

The output terminal 1003 is connected to the photoelectric conversion element 1001 that is arranged at one end of the plurality of photoelectric conversion elements 1001 connected in series.

The output terminal 1004 is connected to the photoelectric conversion element 1001 that is arranged at the other end of the plurality of photoelectric conversion elements 1001 connected in series.

As described above, the photoelectric conversion elements 100, 200, 300, 400, 500, 600, 700, 800, and 900 have tolerance to photodegradation and exhibit high reliability.

Therefore, the reliability of the photoelectric conversion module 1000 can be significantly increased.

The photoelectric conversion module according to the tenth embodiment is not limited to the configuration illustrated in FIG. 33 and may have any configuration provided that any of the photoelectric conversion elements 100, 200, 300, 400, 500, 600, 700, 800, and 900 is used.

### Eleventh Embodiment

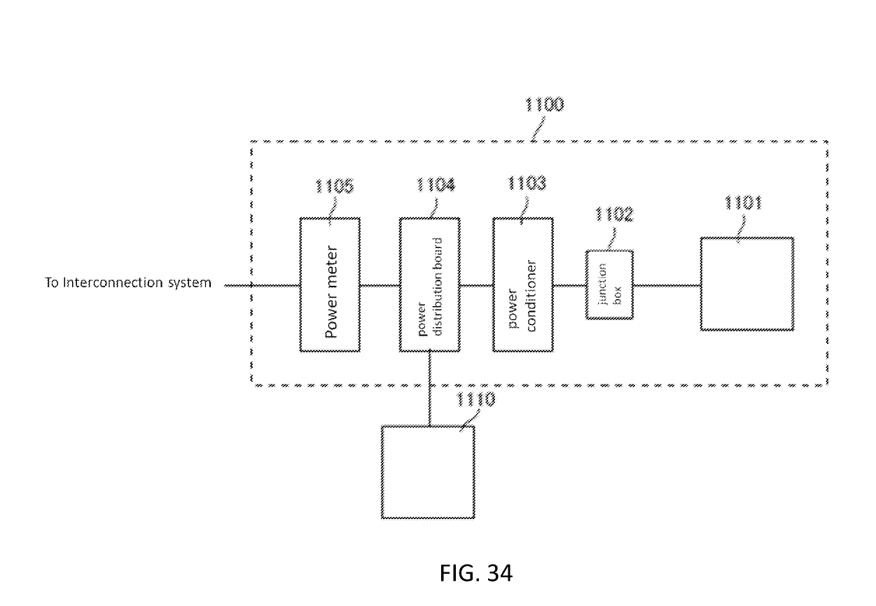

FIG. 34 is a schematic diagram illustrating a configuration of a solar power generation system that includes the photoelectric conversion element according to the above embodiments.

With reference to FIG. 34, a solar power generation system 1100 includes a photoelectric conversion module array 1101, a junction box 1102, a power conditioner 1103, a power distribution board 1104, and a power meter 1105.

The junction box 1102 is connected to the photoelectric conversion module array 1101. The power conditioner 1103 is connected to the junction box 1102. The power distribution board 1104 is connected to the power conditioner 1103 and to an electrical device 1110. The power meter 1105 is connected to the power distribution board 1104 and to an interconnection system.

The photoelectric conversion module array 1101 converts sunlight into electricity to generate direct current power and supplies the generated direct current power to the junction box 1102.

The junction box 1102 receives direct current power generated by the photoelectric conversion module array 1101 and supplies the received direct current power to the power conditioner 1103.

The power conditioner 1103 converts direct current power received from the junction box 1102 into alternating current power and supplies the converted alternating current power to the power distribution board 1104.

The power distribution board 1104 supplies alternating current power received from the power conditioner 1103 and/or commercial power received through the power meter 1105 to the electrical device 1110. When the alternating current power received from the power conditioner 1103 is greater than the power consumed by the electrical device 1110, the power distribution board 1104 supplies the alternating current power surplus to the interconnection system through the power meter 1105.

The power meter 1105 measures power in a direction from the interconnection system to the power distribution board 1104 and measures power in a direction from the power distribution board 1104 to the interconnection system.

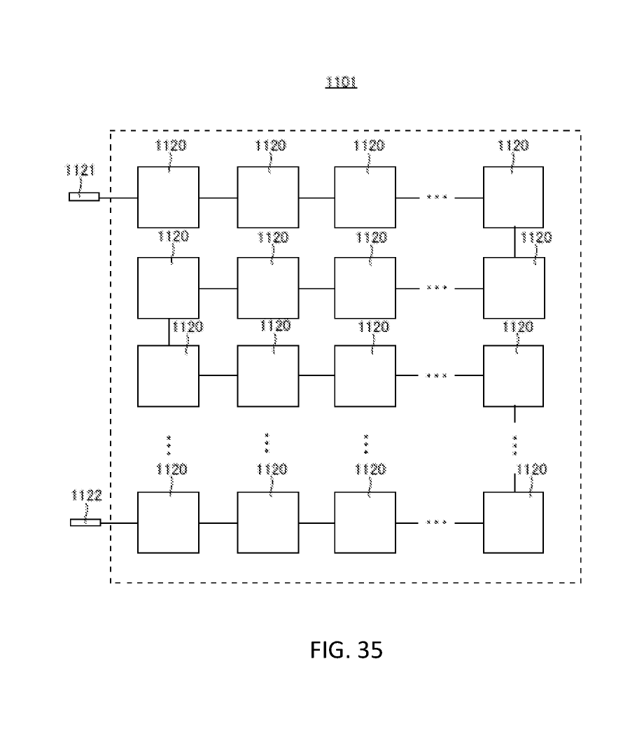

FIG. 35 is a schematic diagram illustrating a configuration of the photoelectric conversion module array 1101 illustrated in FIG. 34.

With reference to FIG. 35, the photoelectric conversion module array 1101 includes a plurality of photoelectric conversion modules 1120 and output terminals 1121 and 1122.

The plurality of photoelectric conversion modules 1120 is arranged in an array form and is connected in series. The plurality of photoelectric conversion modules 1120 may be connected in parallel instead of being connected in series or may be connected by combining serial connection and parallel connection. Each of the plurality of photoelectric conversion modules 1120 is configured of the photoelectric conversion module 1000 illustrated in FIG. 33.

The output terminal 1121 is connected to the photoelectric conversion module 1120 that is positioned at one end of the plurality of photoelectric conversion modules 1120 connected in series.

The output terminal 1122 is connected to the photoelectric conversion module 1120 that is positioned at the other end of the plurality of photoelectric conversion modules 1120 connected in series.

Operations in the solar power generation system 1100 will be described. The photoelectric conversion module array 1101 converts sunlight into electricity to generate direct current power and supplies the generated direct current power to the power conditioner 1103 through the junction box 1102.

The power conditioner 1103 converts direct current power received from the photoelectric conversion module array 1101 into alternating current power and supplies the converted alternating current power to the power distribution board 1104.

The power distribution board 1104 supplies alternating current power received from the power conditioner 1103 to the electrical device 1110 when the alternating current power received from the power conditioner 1103 is greater than or equal to the power consumed by the electrical device 1110. The power distribution board 1104 supplies the alternating current power surplus to the interconnection system through the power meter 1105.

The power distribution board 1104 supplies alternating current power received from the interconnection system and alternating current power received from the power conditioner 1103 to the electrical device 1110 when the alternating current power received from the power conditioner 1103 is less than the power consumed by the electrical device 1110.

The solar power generation system 1100 includes any of the photoelectric conversion elements 100, 200, 300, 400, 500, 600, 700, 800, and 900 that have tolerance to photodegradation and exhibit high reliability as described above.

Therefore, the reliability of the solar power generation system 1100 can be significantly increased.

The solar power generation system according to the eleventh embodiment is not limited to the configuration illustrated in FIGS. 34 and 35 and may have any configuration provided that any of the photoelectric conversion elements 100, 200, 300, 400, 500, 600, 700, 800, and 900 is used.

### Twelfth Embodiment

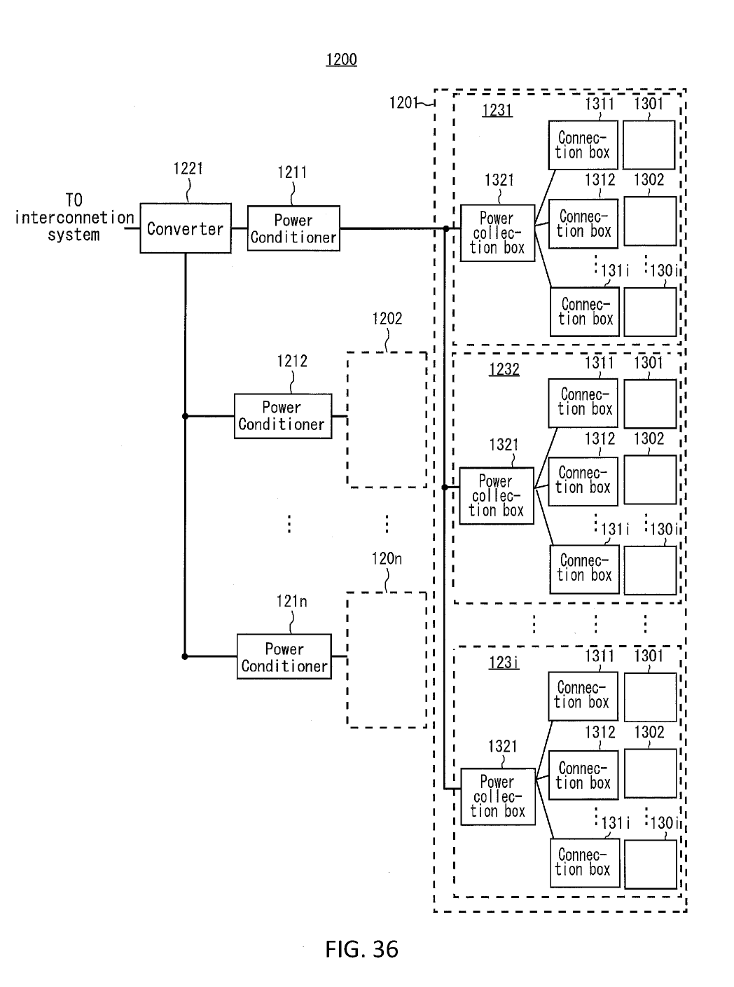

FIG. 36 is a schematic diagram illustrating a configuration of a solar power generation system that includes the photoelectric conversion element according to the above embodiments.

With reference to FIG. 36, a solar power generation system 1200 includes subsystems 1201 to 120n (n is an integer greater than or equal to two), power conditioners 1211 to 121n, and a transformer 1221. The solar power generation system 1200 is a solar power generation system that is greater in size than the solar power generation system 1100 illustrated in FIG. 34.

The power conditioners 1211 to 121n are respectively connected to the subsystems 1201 to 120n.

The transformer 1221 is connected to the power conditioners 1211 to 121n and to an interconnection system.

Each of the subsystems 1201 to 120n is configured of module systems 1231 to 123j (j is an integer greater than or equal to two).

Each of the module systems 1231 to 123j includes photoelectric conversion module arrays 1301 to 130i (i is an integer greater than or equal to two), junction boxes 1311 to 131i, and a collector box 1321.

Each of the photoelectric conversion module arrays 1301 to 130i has the same configuration as the photoelectric conversion module array 1101 illustrated in FIG. 35.

The junction boxes 1311 to 131i are respectively connected to the photoelectric conversion module arrays 1301 to 130i.

The collector box 1321 is connected to the junction boxes 1311 to 131i. The j number of collector boxes 1321 of the subsystem 1201 are connected to the power conditioner 1211. The j number of collector boxes 1321 of the subsystem 1202 are connected to the power conditioner 1212. Hereinafter, similarly, the j number of collector boxes 1321 of the subsystem 120n will be connected to the power conditioner 121n.

The i number of photoelectric conversion module arrays 1301 to 130i of the module system 1231 convert sunlight into electricity to generate direct current power and supply the generated direct current power to the collector box 1321 respectively through the junction boxes 1311 to 131i. The i number of photoelectric conversion module arrays 1301 to 130i of the module system 1232 convert sunlight into electricity to generate direct current power and supply the generated direct current power to the collector box 1321 respectively through the junction boxes 1311 to 131i. Hereinafter, similarly, the i number of photoelectric conversion module arrays 1301 to 130i of the module system 123j will convert sunlight into electricity to generate direct current power and supply the generated direct current power to the collector box 1321 respectively through the junction boxes 1311 to 131i.

The j number of collector boxes 1321 of the subsystem 1201 supply direct current power to the power conditioner 1211.

Similarly, the j number of collector boxes 1321 of the subsystem 1202 supply direct current power to the power conditioner 1212.

Hereinafter, similarly, the j number of collector boxes 1321 of the subsystem 120n will supply direct current power to the power conditioner 121n.

The power conditioners 1211 to 121n convert direct current power respectively received from the subsystem 1201 to 120n into alternating current power and supply the converted alternating current power to the transformer 1221.

The transformer 1221 receives alternating current power from the power conditioners 1211 to 121n and converts and supplies the voltage level of the received alternating current power to the interconnection system.

The solar power generation system 1200 includes any of the photoelectric conversion elements 100, 200, 300, 400, 500, 600, 700, 800, and 900 that have tolerance to photodegradation and exhibit high reliability as described above.

Therefore, the reliability of the solar power generation system 1200 can be significantly increased.

The solar power generation system according to the twelfth embodiment is not limited to the configuration illustrated in FIG. 36 and may have any configuration provided that any of the photoelectric conversion elements 100, 200, 300, 400, 500, 600, 700, 800, and 900 is used.

While described above are the photoelectric conversion elements 100, 200, 300, and 400 in which junctions on the rear surface side thereof where currents are obtained are heterojunctions, the photoelectric conversion element according to the embodiments of the invention is not limited thereto, and junctions on the rear surface side may be homojunctions. In this case, a p-type diffusion region and an n-type diffusion region are alternately formed in the in-plane direction of a crystalline silicon substrate on the rear surface side of the crystalline silicon substrate. In a case where the crystalline silicon substrate is configured of an n-type monocrystalline silicon substrate or an n-type polycrystalline silicon substrate, the area occupancy made by the p-type diffusion region is preferably greater than the area occupancy made by the n-type diffusion region. In a case where the crystalline silicon substrate is configured of a p-type monocrystalline silicon substrate or a p-type polycrystalline silicon substrate, the area occupancy made by the n-type diffusion region is preferably greater than the area occupancy made by the p-type diffusion region.

As such, also in a case where junctions on the rear surface side are homojunctions, the photoelectric conversion element includes the non-crystalline thin film 2 on the light incident side. Thus, ultraviolet light is absorbed, and photodegradation of the photoelectric conversion element can be reduced.

Above, described is the photoelectric conversion element that includes the non-crystalline thin film 2 on the surface on the light incident side of the crystalline silicon substrate and in which junctions on the rear surface side are either heterojunctions or homojunctions, and also described are various types of structures for the structure of the non-crystalline thin film 2. In addition, described are the photoelectric conversion elements 500, 600, 700, 800, and 900 in which junctions exist on the light incident side. Therefore, the photoelectric conversion element according to the embodiments of the invention may include a crystalline silicon substrate, a passivation film that is disposed on the surface on the light incident side of the crystalline silicon substrate and includes a hydrogen atom, and an non-crystalline thin film that is disposed further on the light incident side than the passivation film, in which the non-crystalline thin film absorbs at least a part of light having a wavelength corresponding to energy greater than or equal to the bond energy between the hydrogen atom and an atom other than the hydrogen atom constituting the passivation film.

The reason is that if at least a part of light having a wavelength corresponding to energy greater than or equal to the bond energy between the hydrogen atom and an atom other than the hydrogen atom constituting the passivation film is absorbed, an increase of defects in the passivation film due to ultraviolet light is suppressed, and photodegradation of the photoelectric conversion element can be reduced.

It is to be considered that the embodiments currently disclosed are for illustrative purposes from every point of view and do not limit the invention. It is intended that the scope of the present invention is shown by the claims and not by the above descriptions of the embodiments and includes all modifications carried out within the meaning and the scope equivalent to the claims.

### INDUSTRIAL APPLICABILITY

The invention is applied to a photoelectric conversion element.

1. A photoelectric conversion element comprising:
a semiconductor substrate;
a passivation film that is disposed on a surface on a light incident side of the semiconductor substrate and includes a hydrogen atom; and
an non-crystalline thin film that is disposed further on the light incident side than the passivation film,
wherein the non-crystalline thin film absorbs at least a part of light having a wavelength corresponding to energy greater than or equal to bond energy between the hydrogen atom and an atom other than the hydrogen atom constituting the passivation film.

2. The photoelectric conversion element according to claim 1,
wherein the optical band gap of the non-crystalline thin film is greater than the optical band gap of the passivation film.

3. The photoelectric conversion element according to claim 1,
wherein the non-crystalline thin film includes a main constituent element of the passivation film and a desired element that is for setting the optical band gap of the non-crystalline thin film to an optical band gap greater than the optical band gap of the passivation film.

4. The photoelectric conversion element according to claim 1,
wherein the passivation film includes an Si—H bond, and
the wavelength is less than or equal to 365 nm.

5. The photoelectric conversion element according to claim 1,
wherein the composition ratio of nitrogen atoms with respect to silicon atoms in the non-crystalline thin film is greater than 0 and less than 0.85.
